(19) United States
(12) Patent Application Publication
(10) Pub. No.: US 2012/0032163 A1
(43) Pub. Date: Feb. 9, 2012

(54) SEMICONDUCTOR DEVICE AND METHOD FOR MANUFACTURING THE SAME

(75) Inventor: Shunpei YAMAZAKI, Setagaya (JP)

(73) Assignee: SEMICONDUCTOR ENERGY LABORATORY CO., LTD., Atsugi-shi (JP)

(21) Appl. No.: 13/193,771

(22) Filed: Jul. 29, 2011

(30) Foreign Application Priority Data
Aug. 6, 2010 (JP) 2010-178174

(51) Int. Cl. H01L 29/786; H01L 21/363

(52) U.S. Cl. 257/43; 438/104; 257/E21.462; 257/E29.296

(57) ABSTRACT

The electric characteristics of a semiconductor device including an oxide semiconductor change by irradiation with visible light or ultraviolet light. In view of the above problem, one object is to provide a semiconductor device including an oxide semiconductor film, which has stable electric characteristics and high reliability. Over an oxide insulating layer, a first oxide semiconductor layer is formed to a thickness greater than or equal to 1 nm and less than or equal to 10 nm and crystallized by heat treatment, so that a first crystalline oxide semiconductor layer is formed. A second crystalline oxide semiconductor layer with a greater thickness than the first crystalline oxide semiconductor layer is formed thereover.

### BACKGROUND OF THE INVENTION

1. Field of the Invention

An embodiment of the present invention relates to a semiconductor device including an oxide semiconductor and a manufacturing method thereof.

In this specification, a semiconductor device generally means a device which can function by utilizing semiconductor characteristics, and an electrooptic device, a semiconductor circuit, and electronic equipment are all semiconductor devices.

2. Description of the Related Art

In recent years, a technique for forming thin film transistors (TFTs) using a thin semiconductor film (with a thickness of from several tens of nanometers to several hundreds of nanometers, approximately) formed over a substrate having an insulating surface has been attracting attention. Thin film transistors are applied to a wide range of electronic devices such as ICs or electro-optical devices, and prompt development of thin film transistors that are to be used as switching elements in image display devices, in particular, is being pushed. Various metal oxides are used for a variety of applications.

Some metal oxides have semiconductor characteristics. The examples of such metal oxides having semiconductor characteristics are a tungsten oxide, a tin oxide, an indium oxide, a zinc oxide, and the like. A thin film transistor in which a channel formation region is formed using such metal oxides having semiconductor characteristics is known (Patent Documents 1 and 2).

### REFERENCE

[Patent Document 1] Japanese Published Patent Application No. 2007-123861
[Patent Document 2] Japanese Published Patent Application No. 2007-096055

### SUMMARY OF THE INVENTION

When hydrogen or water, which forms an electron donor, enters an oxide semiconductor in a process for manufacturing a device, the electrical conductivity of the oxide semiconductor may change. Such a phenomenon becomes a factor of variation in the electric characteristics of a transistor using the oxide semiconductor.

Further, the electric characteristics of a semiconductor device using an oxide semiconductor change by irradiation with visible light or ultraviolet light.

In view of the above problems, one object is to provide a semiconductor device including an oxide semiconductor film, which has stable electric characteristics and high reliability.

Further, another object is to provide a manufacturing process of a semiconductor device, which enables mass production of highly reliable semiconductor devices by using a large-sized substrate such as a mother glass.

An embodiment of the invention to be disclosed is a semiconductor device including a first crystalline oxide semiconductor layer with a thickness greater than or equal to 1 nm and less than or equal to 10 nm, which is provided over an oxide insulating layer, and a second crystalline oxide semiconductor layer with a greater thickness than the first crystalline oxide semiconductor layer, which is provided over the first crystalline oxide semiconductor layer. Note that the first crystalline oxide semiconductor layer or the second crystalline oxide semiconductor layer includes a material containing at least Zn and has c-axis alignment. It is preferable that the first crystalline oxide semiconductor layer or the second crystalline oxide semiconductor layer includes a material containing at least Zn and In. With the above structure, a highly reliable semiconductor device which has stable electric characteristics is provided.

In formation of the first crystalline oxide semiconductor layer, deposition is performed by a sputtering method in which a substrate temperature is higher than or equal to 200° C. and lower than or equal to 400° C., and after the deposition, a first heat treatment (at a temperature higher than or equal to 400° C. and lower than or equal to 750° C.) is performed. Depending on the substrate temperature at the time of deposition or the temperature of the first heat treatment, the deposition and the first heat treatment cause crystallization from a film surface and the crystal grows from the film surface toward the inside of the film; thus, c-axis aligned crystal is obtained. By the first heat treatment, a large amount of zinc and oxygen gather to the film surface, and one or more layers of graphene-type two-dimensional crystal including zinc and oxygen and having a hexagonal upper plane (a schematic plan view thereof is shown in FIG. 23A) are formed at the outermost surface; the layers of crystal at the outermost surface grow in the thickness direction to form a stack of layers. In FIG. 23A, a white circle indicates a zinc atom, and a black circuit indicates an oxygen atom. By increasing the temperature of the heat treatment, crystal growth proceeds from the surface to the inside and further from the inside to the bottom. Further, FIG. 23B schematically shows a stacked layer formed of six layers of two-dimensional crystal as an example of a stacked layer in which two-dimensional crystal has grown.

By the first heat treatment, oxygen in an oxide insulating layer is diffused to an interface between the oxide insulating layer and the first crystalline oxide semiconductor layer or the vicinity of the interface (within ±5 nm from the interface), whereby oxygen vacancy in the first crystalline oxide semiconductor layer is reduced. Therefore, it is preferable to contain a large amount of oxygen which exceeds at least the stoichiometry in (in a bulk of) the oxide insulating layer used as a base insulating layer or at the interface between the first crystalline oxide semiconductor layer and the oxide insulating layer.

In formation of the second crystalline oxide semiconductor layer, deposition is performed by a sputtering method in which a substrate temperature is higher than or equal to 200° C. and lower than or equal to 400° C. By setting the substrate temperature in the deposition to be higher than or equal to 200° C. and lower than or equal to 400° C., precursors can be arranged in the oxide semiconductor layer formed over and in contact with the surface of the first crystalline oxide semiconductor layer and so-called orderliness can be obtained. Then, a second heat treatment is preferably performed at a temperature higher than or equal to 400° C. and lower than or equal to 750° C. after the deposition. The second heat treatment is performed in a nitrogen atmosphere, an oxygen atmosphere, or a mixed atmosphere of argon and oxygen, whereby the density of the second crystalline oxide semiconductor layer is increased and the number of defects therein is reduced. By the second heat treatment, crystal growth proceeds in the thickness direction with the use of the first crystalline oxide semiconductor layer as a nucleus, that is, crystal growth proceeds from the bottom to the inside; thus, the second crystalline oxide semiconductor layer is formed.

The thus obtained stack of the first crystalline oxide semiconductor layer and the second crystalline oxide semiconductor layer is used for a transistor, whereby the transistor can have high reliability and stable electric characteristics. Further, by setting a temperature of the first heat treatment and the second heat treatment to be lower than or equal to 450° C., mass production of highly reliable semiconductor devices can be performed with use of a large-sized substrate such as a mother glass.

An embodiment of the present invention to be disclosed is a method for manufacturing a semiconductor device including steps of forming a first crystalline oxide semiconductor layer with a thickness greater than or equal to 1 nm and less than or equal to 10 nm over an oxide insulating layer, forming a second crystalline oxide semiconductor layer with a greater thickness than the first crystalline oxide semiconductor layer over the first crystalline oxide semiconductor layer, forming a source electrode layer or a drain electrode layer over the second crystalline oxide semiconductor layer, forming a gate insulating layer over the source electrode layer or the drain electrode layer, and forming a gate electrode layer over the gate insulating layer. A transistor obtained with use of this method has a top gate structure.

Further, the first crystalline oxide semiconductor layer and the second crystalline oxide semiconductor layer obtained with the above manufacturing method have c-axis alignment. Note that the first crystalline oxide semiconductor layer and the second crystalline oxide semiconductor layer have neither a single crystal structure nor an amorphous structure. The first crystalline oxide semiconductor layer and the second crystalline oxide semiconductor comprise an oxide including a crystal with c-axis alignment (also referred to as C-Axis Aligned Crystal (CAAC)), which has neither a single crystal structure nor an amorphous structure. The first crystalline oxide semiconductor layer and the second crystalline oxide semiconductor layer partly include a crystal grain boundary.

Note that the first crystalline oxide semiconductor layer and the second crystalline oxide semiconductor layer are each formed using an oxide material including at least Zn. For example, a metal oxide including four elements, such as an In—Al—Ga—Zn—O-based material, an In—Al—Ga—Zn—O based material, an In—Si—Ga—Zn—O-based based material, an In—Ga—B—Zn—O-based material, or an In—Sn—Ga—Zn—O-based material; a metal oxide including three elements, such as an In—Ga—Zn—O-based material, an In—Al—Zn—O-based material, an In—Sn—Zn—O-based material, an In—B—Zn—O-based material, a Sn—Ga—Zn—O-based material, an Al—Ga—Zn—O-based material, or a Sn—Al—Zn—O-based material; a metal oxide including two elements, such as an In—Zn—O-based material, a Sn—Zn—O-based material, an Al—Zn—O-based material, or a Zn—Mg—O-based material; a Zn—O-based material; or the like can be used. In addition, the above materials may contain SiO₂. Here, for example, an In—Ga—Zn—O-based material means an oxide containing indium (In), gallium (Ga), and zinc (Zn), and there is no particular limitation on the composition ratio. Further, the In—Ga—Zn—O-based material may contain an element other than In, Ga, and Zn.

Without limitation to the two-layer structure in which the second crystalline oxide semiconductor layer is formed over the first crystalline oxide semiconductor layer, a stacked structure including three or more layers may be formed by repeat a process of deposition and heat treatment for forming a third crystalline oxide semiconductor layer after the second crystalline oxide semiconductor layer is formed.

In the above structure, in order to decrease contact resistance between the source or drain electrode layer and the second crystalline oxide semiconductor layer, it is preferable to form a conductive film using ITO, IZO including zinc oxide and indium oxide, or the like, which functions as an n⁺ layer. As a result, parasitic resistance can be decreased, and the amount of change in on-state current (Ion deterioration) between before and after application of a negative gate stress in a BT test can be suppressed. Note that the n⁺ layer is formed after the second heat treatment.

In the method for manufacturing a semiconductor device, an entrapment vacuum pump is preferably used for evacuating a deposition chamber when the first crystalline oxide semiconductor layer and/or the second crystalline oxide semiconductor layer and/or the gate insulating layer is manufactured. For example, a cryopump, an ion pump, or a titanium sublimation pump is preferably used. The above entrapment vacuum pump functions so as to reduce the amount of hydrogen, water, a hydroxyl group, or a hydride contained in the gate insulating layer and/or the oxide semiconductor film and/or the insulating layer.

Since there is a possibility that hydrogen, water, a hydroxyl group, or a hydride becomes one of factors inhibiting crystallization of the oxide semiconductor film, the manufacturing steps of film deposition, transferring a substrate, and the like are preferably performed in an atmosphere where hydrogen, water, a hydroxyl group, or a hydride is sufficiently reduced.

An embodiment of the invention to be disclosed is not limited to the above structure of a transistor. For example, a top-gate structure in which an oxide semiconductor layer is provided over a source electrode layer and a drain electrode layer may be employed. Another embodiment of the invention to be disclosed is a method for manufacturing a semiconductor device including steps of forming a source electrode layer or a drain electrode layer over an oxide insulating layer, forming a first crystalline oxide semiconductor layer with a thickness greater than or equal to 1 nm and less than or equal to 10 nm over the source electrode layer or the drain electrode layer, forming a second crystalline oxide semiconductor layer with a greater thickness than the first crystalline oxide semiconductor layer over the first crystalline oxide semiconductor layer, forming a gate insulating layer over the second crystalline oxide semiconductor layer, and forming a gate electrode layer over the gate insulating layer.

For example, a bottom-gate structure in which a gate electrode layer is formed first, and then, a gate insulating layer and an oxide semiconductor layer are stacked may be employed. Another embodiment of the invention to be disclosed is a method for manufacturing a semiconductor device including steps of forming a gate electrode layer over an oxide insulating layer, forming a gate insulating layer over the gate electrode layer, forming a source electrode layer or a drain electrode layer over the gate insulating layer, forming a first crystalline oxide semiconductor layer with a thickness greater than or equal to 1 nm and less than or equal to 10 nm over the source electrode layer or the drain electrode layer, and forming a second crystalline oxide semiconductor layer with a thickness lager than the first crystalline oxide semiconductor layer over the first crystalline oxide semiconductor layer.

For example, a bottom-gate structure in which a source electrode layer and a drain electrode layer are formed over an oxide semiconductor layer may be employed. Another embodiment of the invention to be disclosed is a method for manufacturing a semiconductor device including steps of forming a gate electrode layer over an oxide insulating layer, forming a gate insulating layer over the gate electrode layer, forming a first crystalline oxide semiconductor layer with a thickness greater than or equal to 1 nm and less than or equal to 10 nm over the gate insulating layer, forming a second crystalline oxide semiconductor layer with a greater thickness than the first crystalline oxide semiconductor layer over the first crystalline oxide semiconductor layer, and forming a source electrode layer or a drain electrode layer over the second crystalline oxide semiconductor layer.

In the case of the transistor including a stack of a first crystalline oxide semiconductor layer and a second crystalline oxide semiconductor layer, the amount of change in threshold voltage of the transistor between before and after performance of a bias-temperature (BT) stress test can be reduced even when the transistor is irradiated with light; thus, such a transistor has stable electric characteristics.

### BRIEF DESCRIPTION OF THE DRAWINGS

FIGS. 1A to 1E are cross-sectional views illustrating manufacturing steps of one embodiment of the present invention.

FIGS. 2A to 2D are cross-sectional views illustrating manufacturing steps of one embodiment of the present invention.

FIGS. 3A to 3F are cross-sectional views illustrating manufacturing steps of one embodiment of the present invention.

FIGS. 4A to 4E are cross-sectional views illustrating manufacturing steps of one embodiment of the present invention.

FIGS. 5A to 5C are cross-sectional views illustrating manufacturing steps of one embodiment of the present invention, and FIG. 5D is a top view illustrating one embodiment of the present invention.

FIG. 6 is a cross-sectional view illustrating one embodiment of the present invention.

FIG. 7 is a cross-sectional view illustrating one embodiment of the present invention.

FIGS. 8A and 8B are cross-sectional views each illustrating one embodiment of the present invention.

FIGS. 9A and 9B are a cross-sectional view and a top view, respectively, illustrating one embodiment of the present invention.

FIG. 10 is a top view illustrating an example of a manufacturing apparatus used to manufacture one embodiment of the present invention.

FIGS. 11A to 11C are a cross-sectional view, a top view, and a circuit diagram, respectively, illustrating one embodiment of the present invention.

FIGS. 12A to 12C are a block diagram and equivalent circuit diagrams illustrating one embodiment of the present invention.

FIGS. 13A to 13D are external views of electronic devices each illustrating one embodiment of the present invention.

FIG. 14 is a graph showing current vs. voltage characteristics of transistors.

FIGS. 15A and 15B are graphs showing results of BT tests of a transistor.

FIG. 16 is a graph showing results of a −BT test performed while the transistors are irradiated with light.

FIG. 17 is a cross-sectional STEM image.

FIG. 18 is a plan TEM image.

FIG. 19 is a graph showing XRD measurement results.

FIG. 20 is a graph showing current vs. voltage characteristics of transistors (comparison example).

FIGS. 21A and 21B are graphs showing results of BT tests of transistors (comparison example).

FIG. 22 is a graph showing results of a −BT test performed while the transistors are irradiated with light (comparison example).

FIGS. 23A and 23B are diagrams for describing two-dimensional crystal.

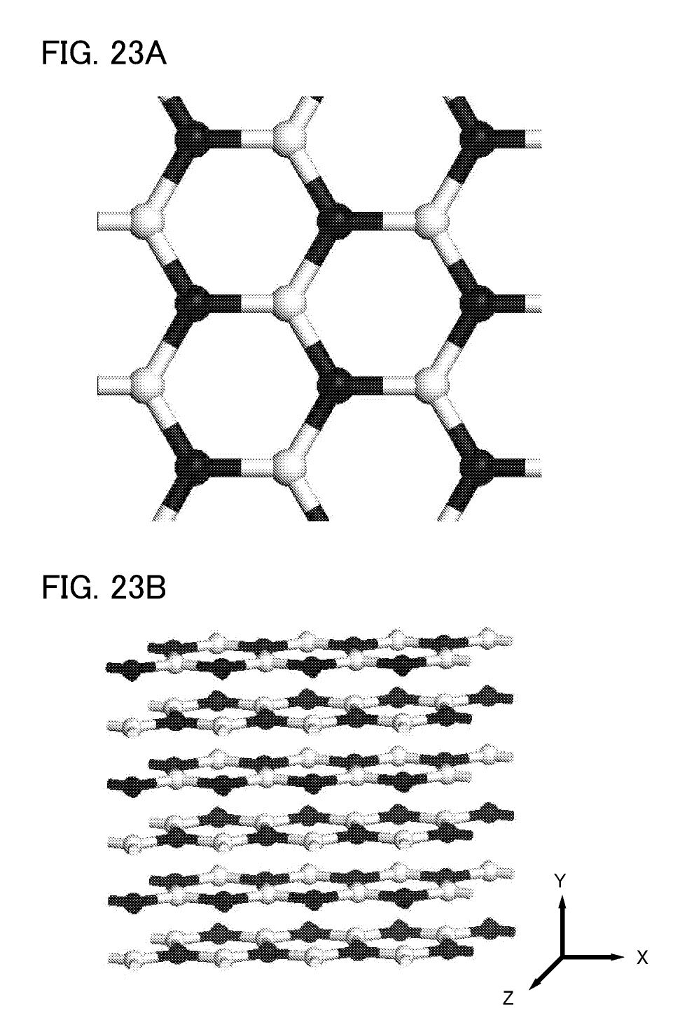

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiments.

### Embodiment 1

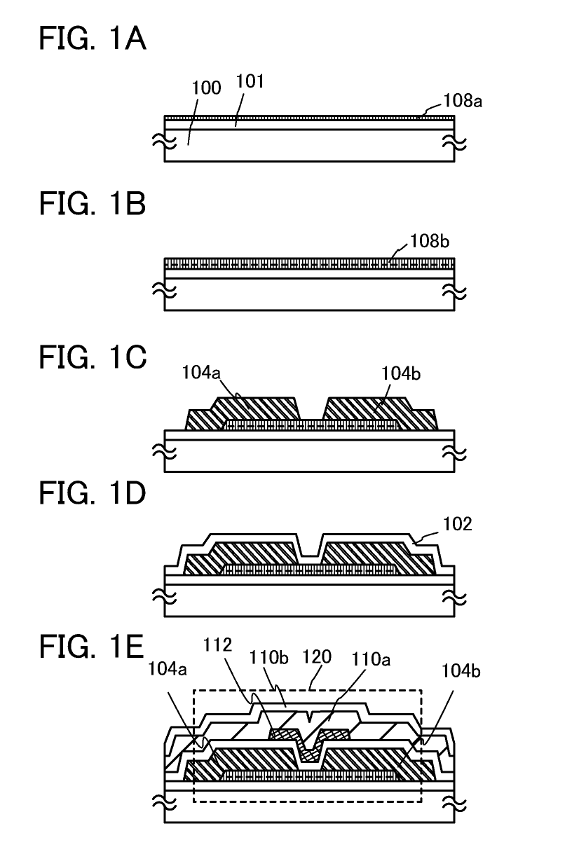

In this embodiment, a structure of a semiconductor device and a manufacturing method thereof will be described with reference to FIGS. 1A to 1E.

FIG. 1E is a cross-sectional view of a top-gate transistor 120. The transistor 120 includes, over a substrate 100 having an insulating surface, an oxide insulating layer 101, a stack of oxide semiconductor layers including a channel formation region, a source electrode layer 104a, a drain electrode layer 104b, a gate insulating layer 102, a gate electrode layer 112, and an oxide insulating film 110a. The source electrode layer 104a and the drain electrode layer 104b are provided to cover end portions of the stack of oxide semiconductor layers, and the gate insulating layer 102 covering the source electrode layer 104a and the drain electrode layer 104b is in contact with part of the stack of oxide semiconductor layers. The gate electrode layer 112 is provided over the part of the stack of oxide semiconductor layers with the gate insulating layer 102 interposed therebetween.

A protective insulating film 110b is provided to cover the oxide insulating film 110a.

In the transistor 120, an electric field is not applied from a top surface of the oxide semiconductor layer to a lower surface thereof, and current does not flow in the thickness direction of the stack of oxide semiconductor layers (in the direction from the top surface to the lower surface, specifically, in the longitudinal direction of FIG. 1E). In the transistor, current mainly flows along an interface between the stack of oxide semiconductor layers; thus, deterioration of the transistor characteristics can be suppressed or reduced even if the transistor is irradiated with light or the BT stress is applied to the transistor.

Hereinafter, a manufacturing process of the transistor 120 over the substrate is described with reference to FIGS. 1A to 1E.

First, the oxide insulating layer 101 is formed over the substrate 100.

As the substrate 100, a non-alkali glass substrate formed with a fusion method or a float method, for example, plastic substrates having heat resistance sufficient to withstand a process temperature of this manufacturing process can be used. In addition, a substrate where an insulating film is provided on a surface of a metal substrate such as a stainless steel substrate, or a substrate where an insulating film is provided on a surface of a semiconductor substrate may be used. In the case where the substrate 100 is mother glass, the substrate may have any of the following sizes: the first generation (320 mm×400 mm), the second generation (400 mm×500 mm), the third generation (550 mm×650 mm), the fourth generation (680 mm×880 mm or 730 mm×920 mm), the fifth generation (1000 mm×1200 mm or 1100 mm×1250 mm), the sixth generation (1500 mm×1800 mm), the seventh generation (1900 mm×2200 mm), the eighth generation (2160 mm×2460 mm), the ninth generation (2400 mm×2800 mm or 2450 mm×3050 mm), the tenth generation (2950 mm×3400 mm), and the like. The mother glass drastically shrinks when the treatment temperature is high and the treatment time is long. Thus, in the case where mass production is performed with use of the mother glass, the preferable heating temperature in the manufacturing process is lower than or equal to 600° C., further preferably, lower than or equal to 450° C.

The oxide insulating layer 101 is formed by a PCVD method or a sputtering method to have a thickness greater than or equal to 50 nm and less than or equal to 600 nm, using one of a silicon oxide film, a gallium oxide film, an aluminum oxide film, a silicon nitride film, a silicon oxynitride film, an aluminum oxynitride film, and a silicon nitride oxide film or a stacked layer including any of the above films. The oxide insulating layer 101 used as a base insulating layer preferably contains a large amount of oxygen which exceeds at least the stoichiometry in (in a bulk of) film. For example, in the case where a silicon oxide film is used, the composition formula is SiO_{2+α}(α>0).

In the case where a glass substrate including an impurity such as alkali metal is used, a silicon nitride film, an aluminum nitride film, or the like may be formed as a nitride insulating layer between the oxide insulating layer 101 and the substrate 100, by a PCVD method or a sputtering method in order to prevent entry of alkali metal. Since alkali metal such as Li or Na is an impurity, it is preferable to reduce the amount of such alkali metal which enters the transistor.

Next, a first oxide semiconductor film with a thickness greater than or equal to 1 nm and less than or equal to 10 nm is formed over the oxide insulating layer 101.

In this embodiment, the first oxide semiconductor film is formed to a thickness of 5 nm in an oxygen atmosphere, an argon atmosphere, or a mixed atmosphere of argon and oxygen under conditions that a target for an oxide semiconductor (a target for an In—Ga—Zn—O-based oxide semiconductor containing In₂O₃, Ga₂O₃, and ZnO at 1:1:2 [molar ratio]) is used, the distance between the substrate and the target is 170 mm, the substrate temperature is 250° C., the pressure is 0.4 Pa, and the direct current (DC) power source is 0.5 kW.

Next, a first heat treatment is performed by setting an atmosphere in a chamber where the substrate is placed to a nitrogen atmosphere or dry air. The temperature of the first heat treatment is higher than or equal to 400° C. and lower than or equal to 750° C. In addition, heating time of the first heat treatment is longer than or equal to 1 minute and shorter than or equal to 24 hours. By the first heat treatment, a first crystalline oxide semiconductor layer 108a is formed (see FIG. 1A).

Next, a second oxide film with a thickness greater than 10 nm is formed over the first crystalline oxide semiconductor layer 108a.

In this embodiment, the second oxide semiconductor film is formed to a thickness of 25 nm in an oxygen atmosphere, an argon atmosphere, or a mixed atmosphere of argon and oxygen under conditions that a target for an oxide semiconductor (a target for an In—Ga—Zn—O-based oxide semiconductor containing In₂O₃, Ga₂O₃, and ZnO at 1:1:2 [molar ratio]) is used, the distance between the substrate and the target is 170 mm, the substrate temperature is 400° C., the pressure is 0.4 Pa, and the direct current (DC) power source is 0.5 kW.

Then, a second heat treatment is performed by setting an atmosphere in a chamber where the substrate is placed to a nitrogen atmosphere or dry air. The temperature of the second heat treatment is higher than or equal to 400° C. and lower than or equal to 750° C. In addition, heating time of the second heat treatment is longer than or equal to 1 minute and shorter than or equal to 24 hours. By the second heat treatment, a second crystalline oxide semiconductor layer 108b is formed (see FIG. 1B).

When the first and second heat treatments are performed at a temperature higher than 750° C., a crack (a crack extended in the thickness direction) is easily generated in the oxide semiconductor layer due to shrink of the glass substrate. Thus, the temperature of heat treatment performed after formation of the first oxide semiconductor film, e.g., the temperatures of the first and second heat treatments, the substrate temperature in deposition by sputtering, or the like is set to lower than or equal to 750° C., preferably lower than or equal to 450° C., whereby a highly reliable transistor can be manufactured over a large-sized substrate.

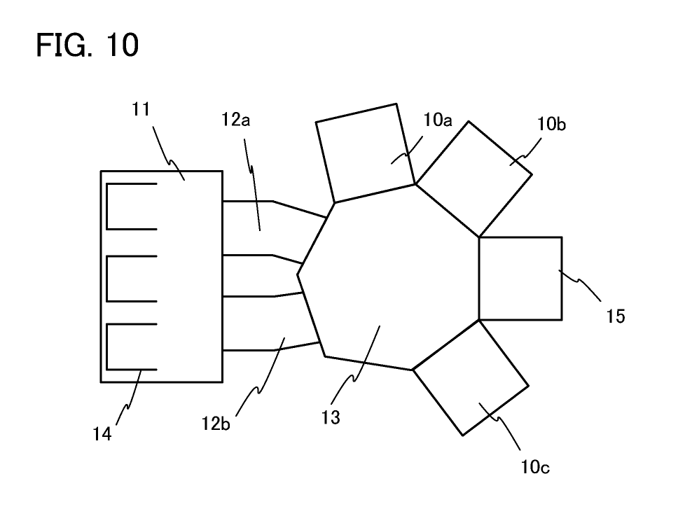

It is preferable that the steps from the formation step of the oxide insulating layer 101 to the step of the second heat treatment be performed successively without exposure to air. For example, a manufacturing apparatus whose top view is illustrated in FIG. 10 may be used. The manufacturing apparatus illustrated in FIG. 10 is the single wafer multi-chamber equipment, which includes three sputtering devices 10a, 10b, and 10c, a substrate supply chamber 11 provided with three cassette ports 14 for holding a process substrate, load lock chambers 12a and 12b, a transfer chamber 13, a substrate heating chamber 15, and the like. Note that a transfer robot for transferring a process substrate is provided in each of the substrate supply chamber 11 and the transfer chamber 13. The atmospheres of the sputtering devices 10a, 10b, and 10c, the transfer chamber 13, and the substrate heating chamber 15 are preferably controlled so as to hardly contain hydrogen and moisture (i.e., as an inert atmosphere, a reduced pressure atmosphere, or a dry air atmosphere). For example, a preferable atmosphere is a dry nitrogen atmosphere in which the dew point of moisture is −40° C. or lower, preferably −50° C. or lower. An example of a procedure of the manufacturing steps with use of the manufacturing apparatus illustrated in FIG. 10 is as follows. The process substrate is transferred from the substrate supply chamber 11 to the substrate heating chamber 15 through the load lock chamber 12a and the transfer chamber 13; moisture attached to the process substrate is removed by vacuum baking in the substrate heating chamber 15; the process substrate is transferred to the sputtering device 10c through the transfer chamber 13; and the oxide insulating layer 101 is deposited in the sputtering device 10c. Then, the process substrate is transferred to the sputtering device 10a through the transfer chamber 13 without exposure to air, and a first oxide semiconductor film is deposited to have a thickness of 5 nm in the sputtering device 10a. Then, the process substrate is transferred to the substrate heating chamber 15 though the transfer chamber 13 without exposure to air and a first heat treatment is performed. Then, the process temperature is transferred to the sputtering device 10b through the transfer chamber 13, and a second oxide semiconductor film is deposited to have a thickness greater than 10 nm in the sputtering device 10b. Then, the process substrate is transferred to the substrate heating chamber 15 through the transfer chamber 13, and a second heat treatment is performed. As described above, with use of the manufacturing apparatus illustrated in FIG. 10, a manufacturing process can proceed without exposure to air. Further, the sputtering device in the manufacturing apparatus in FIG. 10 can achieve a process without exposure to air by changing a sputtering target. For example, the following process can be performed. The substrate over which the oxide insulating layer 101 is formed in advance is placed in the cassette port 14, and the steps from the formation step of the first oxide semiconductor film to the step of the second heat treatment are performed without exposure to air, so that a stack of a first crystalline oxide semiconductor layer and a second crystalline oxide semiconductor layer is formed. After that, in the sputtering device 10c, a conductive film which is formed to be a source electrode layer and a drain electrode layer can be deposited with use of a metal target over the second crystalline oxide semiconductor layer, without exposure to air.

Next, a stack of the first crystalline oxide semiconductor layer 108a and the second crystalline oxide semiconductor layer 108b is processed into an island-shaped stack of oxide semiconductor layers. In the drawings, the interface between the first crystalline oxide semiconductor layer 108a and the second crystalline oxide semiconductor layer 108b is indicated by a dashed line for description of the stack of oxide semiconductor layers. However, a definite interface does not exist. The interface is illustrated for easy description.

The stack of oxide semiconductor layers can be processed by etching after a mask having a desired shape is formed over the stack of oxide semiconductor layers. The mask may be formed by a method such as photolithography. Alternatively, the mask may be formed by a method such as an inkjet method.

For the etching of the stack of oxide semiconductor layers, either wet etching or dry etching may be employed. It is needless to say that both of them may be employed in combination.

Next, a conductive film for forming a source electrode layer and a drain electrode layer (including a wiring formed in the same layer as the source electrode layer and the drain electrode layer) is formed over the stack of oxide semiconductor layers and processed to form the source electrode layer 104a and the drain electrode layer 104b (see FIG. 1C). The source electrode layer 104a and the drain electrode layer 104b can be formed by a sputtering method or the like to have a single-layer structure or a stacked-layer structure using any of metal materials such as molybdenum, titanium, tantalum, tungsten, aluminum, copper, neodymium, and scandium or an alloy material containing any of the above metal materials.

Next, the gate insulating layer 102 is formed to be in contact with part of the stack of oxide semiconductor layers and cover the source electrode layer 104a and the drain electrode layer 104b (see FIG. 1D). The gate insulating layer 102 is an oxide insulating layer, which is formed by a plasma CVD method, a sputtering method, or the like to have a single-layer structure or a stacked-layer structure using any of silicon oxide, silicon oxynitride, silicon nitride oxide, aluminum oxide, gallium oxide, aluminum oxynitride, aluminum nitride oxide, and hafnium oxide, and a combination thereof. The thickness of the gate insulating layer 102 is greater than or equal to 10 nm and less than or equal to 200 nm.

In this embodiment, as the gate insulating layer 102, a silicon oxide film is formed by a sputtering method to have a thickness of 100 nm. After formation of the gate insulating layer 102, a third heat treatment is performed. By the third heat treatment, oxygen is supplied from the gate insulating layer 102 to the stack of oxide semiconductor layers. The higher the temperature of heating treatment is, the more suppressed is the amount of change in the threshold voltage due to a −BT test performed with light irradiation. However, when the heat temperature of the third heat treatment is higher than 320° C., the on-state characteristics are degraded. Thus, the third heat treatment is performed under the conditions that the atmosphere is an inert atmosphere, an oxygen atmosphere, or a mixed atmosphere of oxygen and nitrogen, and the heating temperature is higher than or equal to 200° C. and lower than or equal to 400° C., preferably higher than or equal to 250° C. and lower than or equal to 320° C. In addition, heating time of the third heat treatment is longer than or equal to 1 minute and shorter than or equal to 24 hours.

Next, a conductive film is formed over the gate insulating layer 102 and subjected to a photolithography step, so that the gate electrode layer 112 is formed. The gate electrode layer 112 overlaps with part of the stack of oxide semiconductor layers with the gate insulating layer 102 interposed therebetween. The gate electrode layer 112 can be formed by a sputtering method, or the like to have a single-layer structure or a stacked-layer structure using any of metal materials such as molybdenum, titanium, tantalum, tungsten, aluminum, copper, neodymium, and scandium, or an alloy material which contains any of these materials as a main component.

Next, the insulating film 110a and the insulating film 110b are formed to cover the gate electrode layer 112 and the gate insulating layer 102 (see FIG. 1E).

The insulating film 110a and the insulating film 110b can be formed to have a single-layer structure or a stacked-layer structure using any of silicon oxide, silicon nitride, gallium oxide, silicon oxynitride, silicon nitride oxide, aluminum oxide, aluminum nitride, aluminum oxynitride, aluminum nitride oxide, and hafnium oxide, or a mixed material of these. In this embodiment, as the insulating film 110a, a silicon oxide film with a thickness of 300 nm is formed by a sputtering method, and a heat treatment is performed for an hour at 250° C. in a nitrogen atmosphere. Then, in order to prevent entry of moisture or alkali metal, as the insulating film 110b, a silicon nitride film is formed by a sputtering method. Since alkali metal such as Li or Na is an impurity, the amount of the alkali metal which enters the transistor is preferably reduced. The concentration of the alkali metal in the oxide semiconductor layer is lower than or equal to 2×10¹⁶ cm⁻³, preferably, lower than or equal to 1×10¹⁵ cm⁻³. Although a two-layer structure of the insulating film 110a and the insulating film 110b is exemplified in this embodiment, a single-layer structure may be used.

Through the above process, the transistor 120 having a top gate structure is formed.

In the transistor 120 illustrated in FIG. 1E, the first crystalline oxide semiconductor layer 108a and the second crystalline oxide semiconductor layer 108b are at least partly crystallized and have c-axis alignment. Thus, the highly reliable transistor 120 can be achieved.

Further, in the structure of FIG. 1E, the stack of oxide semiconductor layers of the transistor 120 has orderliness properly in the direction along the interface with the gate insulating layer. In the case where a carrier flows along the interface, the stack of oxide semiconductor layers is in a state close to a floating state; thus, deterioration of the transistor characteristics is suppressed or reduced even if the transistor is irradiated with light or a BT stress is applied to the transistor.

### Embodiment 2

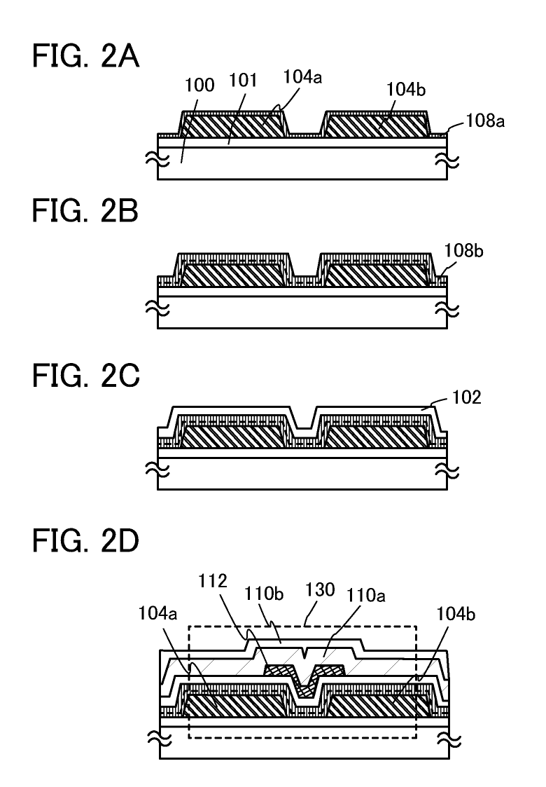

In this embodiment, an example of a process which is partially different from that described in Embodiment 1 will be described with reference to FIGS. 2A to 2D. Note that in FIGS. 2A to 2D, the same reference numerals are used for the same parts as those in FIGS. 1A to 1E, and description of the parts with the same reference numerals is omitted here.

FIG. 2D is a cross-sectional view of a top-gate transistor 130. The transistor 130 includes, over the substrate 100 having an insulating surface, the oxide insulating layer 101, the source electrode layer 104a, the drain electrode layer 104b, the stack of oxide semiconductor layers including a channel formation region, the gate insulating layer 102, the gate electrode layer 112, and the oxide insulating film 110a. The stack of oxide semiconductor layers is provided to cover the source electrode layer 104a and the drain electrode layer 104b. The gate electrode layer 112 is provided over part of the stack of oxide semiconductor layers with the gate insulating layer 102 interposed therebetween.

In addition, the protective insulating film 110b is provided to cover the oxide insulating film 110a.

A process for manufacturing the transistor 130 over the substrate is described below with reference to FIGS. 2A to 2D.

First, the oxide insulating layer 101 is formed over the substrate 100.

Next, a conductive film for forming the source electrode layer and the drain electrode layer (including a wiring formed in the same layer as the source electrode layer and the drain electrode layer) is formed over the oxide insulating layer 101 and processed to form the source electrode layer 104a and the drain electrode layer 104b.

Next, a first oxide semiconductor film is formed to a thickness greater than or equal to 1 nm and less than or equal to 10 nm over the source electrode layer 104a and the drain electrode layer 104b.

Next, a first heat treatment is performed by setting an atmosphere where the substrate is placed to a nitrogen atmosphere or dry air. The temperature of the first heat treatment is higher than or equal to 400° C. and lower than or equal to 750° C. By the first heat treatment, the first crystalline oxide semiconductor layer 108a is formed (see FIG. 2A).

Then, a second oxide semiconductor film with a thickness greater than 10 nm is formed over the first crystalline oxide semiconductor layer 108a.

Then, a second heat treatment is performed by setting an atmosphere where the substrate is placed to a nitrogen atmosphere or dry air. The temperature of the second heat treatment is higher than or equal to 400° C. and lower than or equal to 750° C. By the second heat treatment, the second crystalline oxide semiconductor layer 108b is formed (see FIG. 2B).

Then, if needed, the stack of oxide semiconductor layers including the first crystalline oxide semiconductor layer 108a and the second crystalline oxide semiconductor layer 108b are processed to form an island-shaped stack of oxide semiconductor layers.

Next, the gate insulating layer 102 is formed over the stack of oxide semiconductor layers (see FIG. 2C).

Next, a conductive film is formed over the gate insulating layer 102 and subjected to a photolithography step, so that the gate electrode layer 112 is formed. The gate electrode layer 112 overlaps with part of the stack of oxide semiconductor layers with the gate insulating layer 102 interposed therebetween.

Then, the insulating film 110a and the insulating film 110b are formed to cover the gate electrode layer 112 and the gate insulating layer 102 (see FIG. 2D).

Through the above process, the top-gate transistor 130 is formed.

In the transistor 130 illustrated in FIG. 2D, the first crystalline oxide semiconductor layer 108a and the second crystalline oxide semiconductor layer 108b are at least partly crystallized and have c-axis alignment. Thus, the highly reliable transistor 130 can be achieved.

In the structure of the transistor in FIG. 2D, a carrier is more likely to flow in the thickness direction of the oxide semiconductor layers than that in the transistor structure in FIG. 1E. Such a carrier is likely to be trapped in a defect in the stack of oxide semiconductor layers.

This embodiment can be freely combined with Embodiment 1.

### Embodiment 3

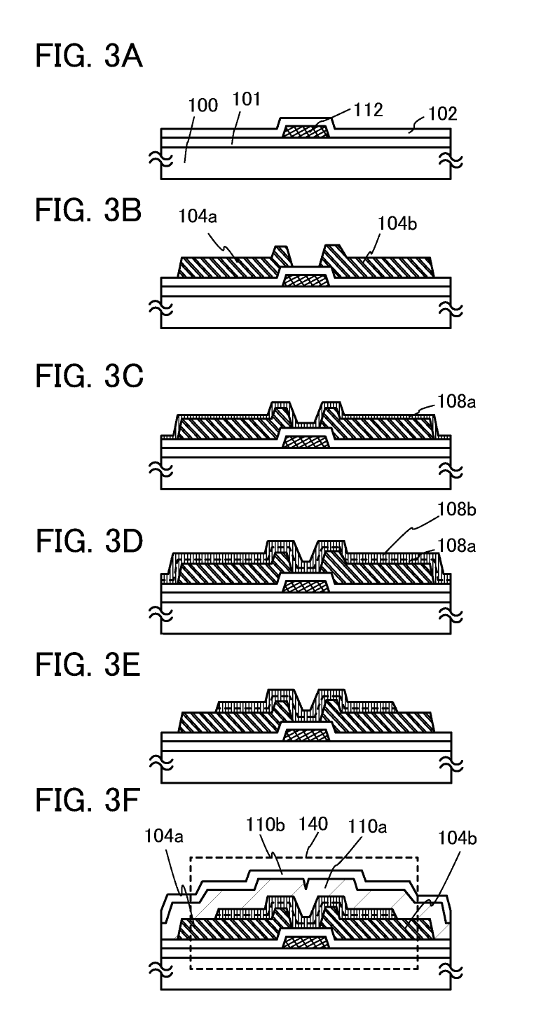

In this embodiment, an example of a process which is partially different from that described in Embodiment 1 will be described with reference to FIGS. 3A to 3F. Note that in FIGS. 3A to 3F, the same reference numerals are used for the same parts as those in FIGS. 1A to 1E, and description of the parts with the same reference numerals is omitted here.

FIG. 3F is a cross-sectional view of a bottom-gate transistor 140. The transistor 140 includes, over the substrate 100 having an insulating surface, the oxide insulating layer 101, the gate electrode layer 112, the gate insulating layer 102, the source electrode layer 104a, the drain electrode layer 104b, the stack of oxide semiconductor layers including a channel formation region, and the oxide insulating film 110a. The stack of oxide semiconductor layers is provided to cover the source electrode layer 104a and the drain electrode layer 104b. A region functioning as a channel formation region is part of the stack of oxide semiconductor layers overlapping with the gate electrode layer 112 with the gate insulating layer 102 interposed therebetween.

In addition, the protective insulating film 110b is provided to cover the oxide insulating film 110a.

A process for manufacturing the transistor 140 over the substrate is described below with reference to FIGS. 3A to 3F.

First, the oxide insulating layer 101 is formed over the substrate 100.

Next, a conductive film is formed over the oxide insulating layer 101 and subjected to a photolithography step, so that the gate electrode layer 112 is formed.

Next, the gate insulating layer 102 is formed over the gate electrode layer 112 (see FIG. 3A).

Next, a conductive film for forming the source electrode layer and the drain electrode layer (including a wiring formed in the same layer as the source electrode layer and the drain electrode layer) is formed over the gate insulating layer 102 and processed to form the source electrode layer 104a and the drain electrode layer 104b (see FIG. 3B).

Next, a first oxide semiconductor film is formed to a thickness greater than or equal to 1 nm and less than or equal to 10 nm over the source electrode layer 104a and the drain electrode layer 104b.

Next, a first heat treatment is performed by setting an atmosphere where the substrate is placed to a nitrogen atmosphere or dry air. The temperature of the first heat treatment is higher than or equal to 400° C. and lower than or equal to 750° C. In addition, heating time of the first heat treatment is longer than or equal to 1 minute and shorter than or equal to 24 hours. By the first heat treatment, the first crystalline oxide semiconductor layer 108a is formed (see FIG. 3C).

Then, a second oxide semiconductor film with a thickness greater than 10 nm is formed over the first crystalline oxide semiconductor layer 108a.

Then, a second heat treatment is performed by setting an atmosphere where the substrate is placed to a nitrogen atmosphere or dry air. The temperature of the second heat treatment is higher than or equal to 400° C. and lower than or equal to 750° C. In addition, heating time of the second heat treatment is longer than or equal to 1 minute and shorter than or equal to 24 hours. By the second heat treatment, the second crystalline oxide semiconductor layer 108b is formed (see FIG. 3D).

Next, the stack of oxide semiconductor layers including the first crystalline oxide semiconductor layer 108a and the second crystalline oxide semiconductor layer 108b is processed to form an island-shaped stack of oxide semiconductor layers (see FIG. 3E).

The stack of oxide semiconductor layers can be processed by etching after a mask having a desired shape is formed over the stack of oxide semiconductor layers. The mask may be formed by a method such as photolithography. Alternatively, the mask may be formed by a method such as an inkjet method.

For the etching of the stack of oxide semiconductor layers, either wet etching or dry etching may be employed. It is needless to say that both of them may be employed in combination.

Next, the insulating film 110a and the insulating film 110b are formed to cover the stack of oxide semiconductor layers, the source electrode layer 104a, and the drain electrode layer 104b (see FIG. 3F).

Through the above process, the bottom-gate transistor 140 is formed.

In the transistor 140 illustrated in FIG. 3F, the first crystalline oxide semiconductor layer 108a and the second crystalline oxide semiconductor layer 108b are at least partly crystallized and have c-axis alignment. Thus, the highly reliable transistor 140 can be achieved.

Further, in the structure of FIG. 3F, the stack of oxide semiconductor layers of the transistor has orderliness properly in the direction along an interface. However, in the structure in FIG. 2D, a carrier flows in the thickness direction of the stack of oxide semiconductor layers, and such a carrier is likely to be trapped in a defect in the stack of oxide semiconductor layers. On the other hand, as in the structure of FIG. 3F, in the case where a carrier flows along the interface, the stack of oxide semiconductor layers is in a state close to a floating state; thus, deterioration of the transistor characteristics is suppressed or reduced even if the transistor is irradiated with light or a BT stress is applied to the transistor.

This embodiment can be freely combined with Embodiment 1.

### Embodiment 4

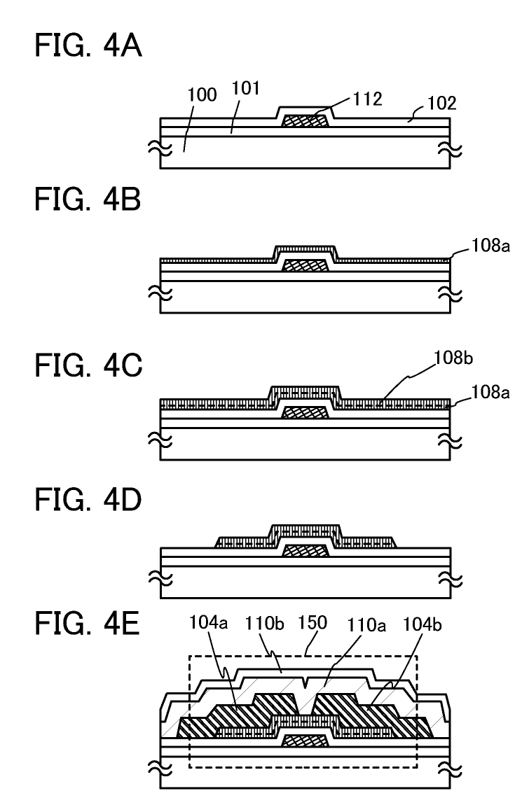

In this embodiment, an example of a process which is partially different from that described in Embodiment 3 will be described with reference to FIGS. 4A to 4E. Note that in FIGS. 4A to 4E, the same reference numerals are used for the same parts as those in FIGS. 3A to 3F, and description of the parts with the same reference numerals is omitted here.

FIG. 4E is a cross-sectional view of a bottom-gate transistor 150. The bottom gate transistor 150 includes, over the substrate 100 having an insulating surface, the oxide insulating layer 101, the gate electrode layer 112, the gate insulating layer 102, the stack of oxide semiconductor layers including a channel formation region, the source electrode layer 104a, the drain electrode layer, 104b, and the oxide insulating film 110a. The source electrode layer 104a and the drain electrode layer 104b are provided to cover the stack of oxide semiconductor layers. A region functioning as a channel formation region is part of the stack of oxide semiconductor layers overlapping with the gate electrode layer 112 with the gate insulating layer 102 interposed therebetween.

In addition, the protective insulating film 110b is provided to cover the oxide insulating film 110a.

A process for manufacturing the transistor 150 over the substrate is described below with reference to FIGS. 4A to 4E.

First, the oxide insulating layer 101 is formed over the substrate 100.

Next, a conductive film is formed over the oxide insulating layer 101 and subjected to a photolithography step, so that the gate electrode layer 112 is formed.

Next, the gate insulating layer 102 is formed over the gate electrode layer 112 (see FIG. 4A).

Next, a first oxide semiconductor film is formed to a thickness greater than or equal to 1 nm and less than or equal to 10 nm over the gate insulating layer 102.

Next, a first heat treatment is performed by setting an atmosphere where the substrate is placed to a nitrogen atmosphere or dry air. The temperature of the first heat treatment is higher than or equal to 400° C. and lower than or equal to 750° C. In addition, heating time of the first heat treatment is longer than or equal to 1 minute and shorter than or equal to 24 hours. By the first heat treatment, the first crystalline oxide semiconductor layer 108a is formed (see FIG. 4B).

Then, a second oxide semiconductor film with a thickness greater than 10 nm is formed over the first crystalline oxide semiconductor layer 108a.

Then, a second heat treatment is performed by setting an atmosphere where the substrate is placed to a nitrogen atmosphere or dry air. The temperature of the second heat treatment is higher than or equal to 400° C. and lower than or equal to 750° C. In addition, heating time of the second heat treatment is longer than or equal to 1 minute and shorter than or equal to 24 hours. By the second heat treatment, the second crystalline oxide semiconductor layer 108b is formed (see FIG. 4C).

Next, the stack of oxide semiconductor layers including the first crystalline oxide semiconductor layer 108a and the second crystalline oxide semiconductor layer 108b is processed to form an island-shaped stack of oxide semiconductor layers (see FIG. 4D).

The stack of oxide semiconductor layers can be processed by etching after a mask having a desired shape is formed over the stack of oxide semiconductor layers. The mask may be formed by a method such as photolithography. Alternatively, the mask may be formed by a method such as an inkjet method.

For the etching of the stack of oxide semiconductor layers, either wet etching or dry etching may be employed. It is needless to say that both of them may be employed in combination.

Next, a conductive film for forming a source electrode layer and a drain electrode layer (including a wiring formed in the same layer as the source electrode layer and the drain electrode layer) is formed over the stack of oxide semiconductor layers and processed to form the source electrode layer 104a and the drain electrode layer 104b.

Next, the insulating film 110a and the insulating film 110b are formed to cover the stack of oxide semiconductor layers, the source electrode layer 104a, and the drain electrode layer 104b (see FIG. 4E). The insulating film 110a is formed using an oxide insulating material, and after film formation, a third heat treatment is preferably performed. By the third heat treatment, oxygen is supplied from the insulating film 110a to the stack of oxide semiconductor layers. The third heat treatment is performed in an inert atmosphere, an oxygen atmosphere, a mixed atmosphere of oxygen and nitrogen, at a temperature higher than or equal to 200° C. and lower than or equal to 400° C., preferably higher than or equal to 250° C. and lower than or equal to 320° C. In addition, heating time of the third heat treatment is longer than or equal to 1 minute and shorter than or equal to 24 hours.

Through the above process, the bottom-gate transistor 150 is formed.

In the transistor 150 illustrated in FIG. 4E, the first crystalline oxide semiconductor layer 108a and the second crystalline oxide semiconductor layer 108b are at least partly crystallized and have c-axis alignment. Thus, the highly reliable transistor 150 can be achieved.

This embodiment can be freely combined with Embodiment 1.

### Embodiment 5

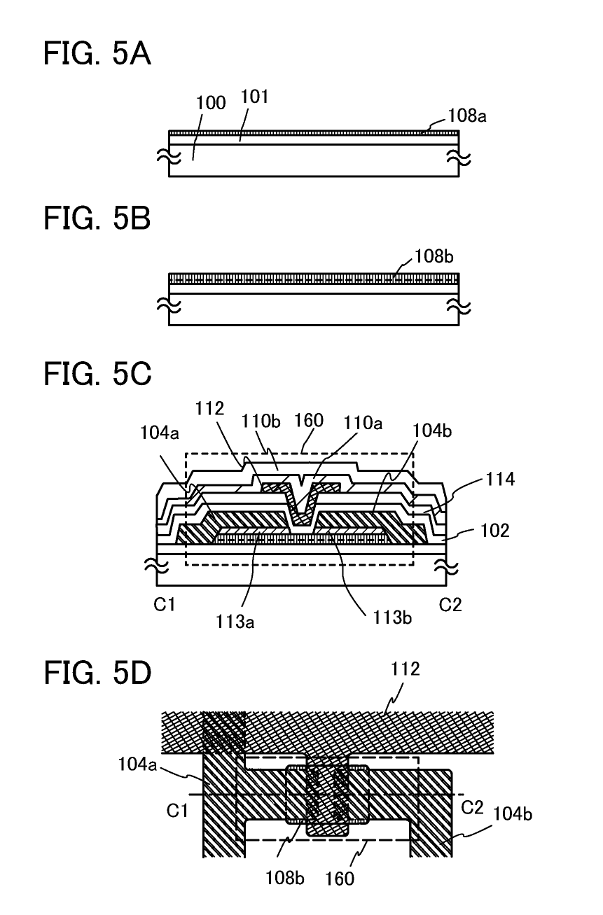

In this embodiment, an example of a structure which is partly different from that described in Embodiment 1 will be described with reference to FIGS. 5A to 5D. Note that in FIGS. 5A to 5D, the same reference numerals are used for the same parts as those in FIGS. 1A to 1E, and description of the parts with the same reference numerals is omitted here.

FIG. 5C illustrates a cross-sectional structure of a top-gate transistor 160 and is a cross-sectional view along a dashed line C1-C2 in FIG. 5D which is a top view. The transistor 160 includes, over the substrate 100 having an insulating surface, the oxide insulating layer 101, the stack of oxide semiconductor layers including a channel formation region, n⁺ layers 113a and 113b, the source electrode layer 104a, the drain electrode layer 104b, the gate insulating layer 102, the gate electrode layer 112, an insulating film 114, and the oxide insulating film 110a. The source electrode layer 104a and the drain electrode layer 104b are provided to cover end portions of the stack of oxide semiconductor layers and end portions of the n⁺ layers 113a and 113b. The gate insulating layer 102 covering the source electrode layer 104a and the drain electrode layer 104b is in contact with part of the stack of oxide semiconductor layers. The gate electrode layer 112 is provided over part of the stack of oxide semiconductor layers with the gate insulating layer 102 interposed therebetween.

The insulating film 114 overlapping with the source electrode layer 104a or the drain electrode layer 104b is provided over the gate insulating layer 102 in order to reduce parasitic capacitance generated between the gate electrode layer 112 and the source electrode layer 104a and parasitic capacitance generated between the gate electrode layer 112 and the drain electrode layer 104b. Further, the gate electrode layer 112 and the insulating film 114 are covered with the oxide insulating film 110a, and the protective insulating film 110b is provided to cover the oxide insulating film 110a.

A process for manufacturing the transistor 160 over the substrate is described below with reference to FIGS. 5A to 5C.

First, the oxide insulating layer 101 is formed over the substrate 100. The oxide insulating layer 101 is formed using a silicon oxide film, a gallium oxide film, an aluminum oxide film, a silicon oxynitiride film, an aluminum oxynitride film, or a silicon nitride oxide film.

Next, a first oxide semiconductor film is formed to a thickness greater than or equal to 1 nm and less than or equal to 10 nm over the oxide insulating layer 101.

In this embodiment, the first oxide semiconductor film is formed to a thickness of 5 nm in an oxygen atmosphere, an argon atmosphere, or a mixed atmosphere of argon and oxygen under conditions that a target for an oxide semiconductor (a target for an In—Ga—Zn—O-based oxide semiconductor containing In₂O₃, Ga₂O₃, and ZnO at 1:1:2 [molar ratio]) is used, the distance between the substrate and the target is 170 mm, the substrate temperature is 400° C., the pressure is 0.4 Pa, and the direct current (DC) power source is 0.5 kW.

Next, a first heat treatment is performed by setting an atmosphere where the substrate is placed to a nitrogen atmosphere or dry air. The temperature of the first heat treatment is higher than or equal to 400° C. and lower than or equal to 750° C. In addition, heating time of the first heat treatment is longer than or equal to 1 minute and shorter than or equal to 24 hours. By the first heat treatment, the first crystalline oxide semiconductor layer 108a is formed (see FIG. 5A).

Then, a second oxide semiconductor film with a thickness greater than 10 nm is formed over the first crystalline oxide semiconductor layer 108a.

In this embodiment, the second oxide semiconductor film is formed to a thickness of 25 nm in an oxygen atmosphere, an argon atmosphere, or a mixed atmosphere of argon and oxygen under conditions that a target for an oxide semiconductor (a target for an In—Ga—Zn—O-based oxide semiconductor containing In₂O₃, Ga₂O₃, and ZnO at 1:1:2 [molar ratio]) is used, the distance between the substrate and the target is 170 mm, the substrate temperature is 400° C., the pressure is 0.4 Pa, and the direct current (DC) power source is 0.5 kW.

Then, a second heat treatment is performed by setting an atmosphere where the substrate is placed to a nitrogen atmosphere or dry air. The temperature of the second heat treatment is higher than or equal to 400° C. and lower than or equal to 750° C. In addition, heating time of the second heat treatment is longer than or equal to 1 minute and shorter than or equal to 24 hours. By the second heat treatment, the second crystalline oxide semiconductor layer 108b is formed (see FIG. 5B).

When the first and second heat treatments are performed at a temperature higher than 750° C., a crack (a crack extended in the thickness direction) is easily generated in the oxide semiconductor layer due to shrink of the glass substrate. Thus, the temperature of heat treatment performed after formation of the first oxide semiconductor film, e.g., the temperatures of the first and second heat treatments, the substrate temperature in deposition by sputtering, or the like is set to lower than or equal to 750° C., preferably lower than or equal to 450° C., whereby a highly reliable transistor can be manufactured over a large-sized substrate.

Next, a film functioning as an n⁺ layer is formed using an In—Zn—O-based material, an In—Sn—O-based material, an In—O-based material, or a Sn—O-based material to have a thickness greater than or equal to 1 nm and less than or equal to 10 nm. In addition, SiO₂ may be contained in the above material for the n⁺ layer. In this embodiment, an In—Sn—O film containing SiO₂ is formed to a thickness of 5 nm.

Next, the stack of oxide semiconductor layers including the first crystalline oxide semiconductor layer 108a and the second crystalline oxide semiconductor layer 108b and the film functioning as an n⁺ layer are processed.

Next, a conductive film for forming the source electrode layer and the drain electrode layer (including a wiring formed in the same layer as the source electrode layer and the drain electrode layer) is formed over the film functioning as an n⁺ layer and processed to form the source electrode layer 104a and the drain electrode layer 104b. Etching is performed when the conductive film is processed or after the conductive film is processed. The film functioning as an n⁺ layer is selectively etched, whereby the second crystalline oxide semiconductor layer 108b is partly exposed. Note that selective etching of the film functioning as an n⁺ layer enables formation of the n⁺ layer 113a which overlaps with the source electrode layer 104a and the n⁺ layer 113b which overlaps with the drain electrode layer 104b. End portions of the n⁺ layers 113a and 113b preferably have a tapered shape.

The source electrode layer 104a and the drain electrode layer 104b can be formed to have a single-layer structure or a stacked-layer structure using any of metal materials such as molybdenum, titanium, tantalum, tungsten, aluminum, copper, neodymium, and scandium, or an alloy material which contains any of these materials as a main component by a sputtering method, or the like.

When the n⁺ layer 113a or 113b is formed between the stack of oxide semiconductor layers and the source electrode layer 104a or the drain electrode layer 104b, the contact resistance can be lower than the contact resistance in the case where the stack of oxide semiconductor layers is in contact with the source electrode layer 104a or the drain electrode layer 104b. In addition, when the n⁺ layers 113a and 113b are formed, the parasitic capacitance can be reduced, and the amount of change in on-state current (Ion deterioration) between before and after application of a negative gate stress in a BT test can be suppressed.

Next, the gate insulating layer 102 is formed to be in contact with an exposed part of the stack of oxide semiconductor layers and cover the source electrode layer 104a and the drain electrode layer 104b. The gate insulating layer 102 is preferably formed using an oxide insulating material, and after film formation, a third heat treatment is preferably performed. By the third heat treatment, oxygen is supplied from the gate insulating layer 102 to the stack of oxide semiconductor layers. The third heat treatment is performed in an inert atmosphere, an oxygen atmosphere, a mixed atmosphere of oxygen and nitrogen, at a temperature higher than or equal to 200° C. and lower than or equal to 400° C., preferably higher than or equal to 250° C. and lower than or equal to 320° C. In addition, heating time of the third heat treatment is longer than or equal to 1 minute and shorter than or equal to 24 hours.

Then, an insulating film is formed over the gate insulating layer 102, and part of the insulating film, overlapping with a region where the gate insulating layer 102 is in contact with the second crystalline oxide semiconductor layer 108b, is selectively removed, so that part of the gate insulating layer 102 is exposed.

The insulating film 114 functions to reduce the parasitic capacitance generated between the source electrode layer 104a and the gate electrode layer formed later or the parasitic capacitance generated between the drain electrode layer 104b and the gate electrode layer formed later. Note that the insulating film 114 can be formed using silicon oxide, silicon nitride, aluminum oxide, or gallium oxide; a mixed material thereof; or the like.

Next, a conductive film is formed over the gate insulating layer 102 and subjected to a photolithography step, so that the gate electrode layer 112 is formed. The gate electrode layer 112 can be formed by a sputtering method, or the like to have a single-layer structure or a stacked-layer structure using any of metal materials such as molybdenum, titanium, tantalum, tungsten, aluminum, copper, neodymium, and scandium, or an alloy material which contains any of these materials as a main component.

Next, the insulating film 110a and the insulating film 110b are formed to cover the gate electrode layer 112 and the insulating film 114 (see FIG. 5C).

The insulating film 110a and the insulating film 110b can be formed to have a single-layer structure or a stacked-layer structure using any of materials such as silicon oxide, silicon nitride, gallium oxide, silicon oxynitride, silicon nitride oxide, aluminum oxide, aluminum nitride, aluminum oxynitride, aluminum nitride oxide, and hafnium oxide, or a mixed material of these.

Through the above process, the top-gate transistor 160 is formed.

In the transistor 160 illustrated in FIG. 5C, the first crystalline oxide semiconductor layer 108a and the second crystalline oxide semiconductor layer 108b are at least partly crystallized and have c-axis alignment. Thus, the highly reliable transistor 160 can be achieved.

Further, in the structure of FIG. 5C, the stack of oxide semiconductor layers of the transistor 160 has orderliness properly in the direction along an interface with the gate insulating layer. In the case where a carrier flows along the interface, the stack of oxide semiconductor layers is in a state close to a floating state; thus, deterioration of the transistor characteristics is suppressed or reduced even if the transistor is irradiated with light or a BT stress is applied to the transistor.

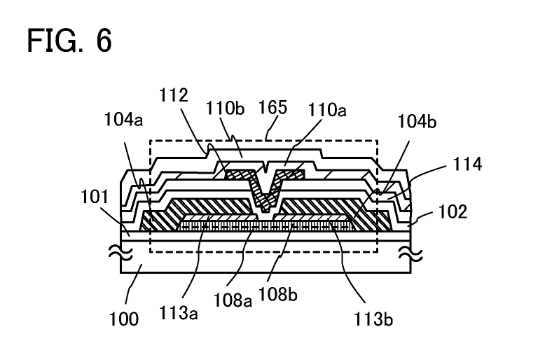

Further, FIG. 6 illustrates an example of a transistor 165 in which an end portion of the n⁺ layer 113a is protruded from the source electrode layer 104a and an end portion of the n⁺ layer 113b is protruded from the drain electrode layer 104b by processing of the film functioning as an n⁺ layer. In the transistor 165, the distance between the n⁺ layer 113a and the n⁺ layer 113b is smaller than that in FIG. 5C, whereby a channel length is shortened, and accordingly, high speed operation is achieved.

This embodiment can be freely combined with Embodiment 1.

### Embodiment 6

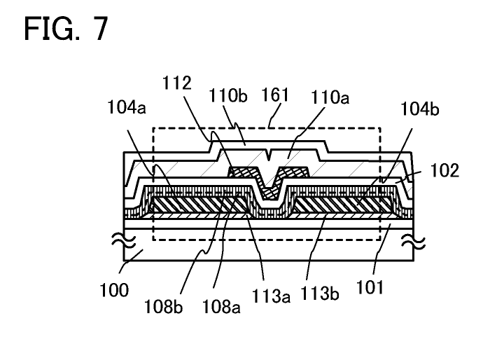

In this embodiment, an example of a structure which is partly different from that described in Embodiment 2 will be described with reference to FIG. 7. Note that in FIG. 7, the same reference numerals are used for the same parts as those in FIGS. 2A to 2D, and description of the parts with the same reference numerals is omitted here.

FIG. 7 is a cross-sectional view of a top-gate transistor 161. The transistor 161 includes, over the substrate 100 having an insulating surface, the oxide insulating layer 101, the n⁺ layers 113a and 113b, the source electrode layer 104a, the drain electrode layer 104b, the stack of oxide semiconductor layers including a channel formation region, the gate insulating layer 102, the gate electrode layer 112, and the oxide insulating film 110a. The stack of oxide semiconductor layers (the first crystalline oxide semiconductor layer 108a and the second crystalline oxide semiconductor layer 108b) is provided to cover the source electrode layer 104a and the drain electrode layer 104b. The gate electrode layer 112 is provided over part of the stack of oxide semiconductor layers with the gate insulating layer 102 interposed therebetween.

In addition, the protective insulating film 110b is provided to cover the oxide insulating film 110a.

A manufacturing process of the transistor 161 is the same as that of the transistor illustrated in FIG. 2D, except for a step in which the n⁺ layers 113a and 113b are provided. The step different from that in FIGS. 2A to 2D is described below.

After the oxide insulating layer 101 is formed over the substrate 100, using an In—Zn—O-based material, an In—Sn—O-based material, an In—O-based material, or a Sn—O-based material, a film functioning as an n⁺ layer is formed to a thickness greater than or equal to 1 nm and less than or equal to 10 nm. In addition, SiO₂ may be contained in the above material for the n⁺ layer. In this embodiment, an In—Sn—O film is formed to a thickness of 5 nm.

Next, a conductive film for forming the source electrode layer and the drain electrode layer is formed and processed, so that the source electrode layer 104a and the drain electrode layer 104b are formed.

Then, the film functioning as an n⁺ layer is processed, so that the n⁺ layer 113a is formed to be protruded from the source electrode layer 104a and the n⁺ layer 113b is formed to be protruded from the drain electrode layer 104b. Thus, the channel length of the transistor illustrated in FIG. 7 is determined by a distance between the n⁺ layer 113a and the n⁺ layer 113b. On the other hand, the channel length of the transistor illustrated in FIG. 2D is determined by the distance between the source electrode layer 104a and the drain electrode layer 104b.

Next, a first oxide semiconductor film is formed to a thickness greater than or equal to 1 nm and less than or equal to 10 nm over the source electrode layer 104a and the drain electrode layer 104b. Since the subsequent steps are the same as those in Embodiment 2, the detailed description is omitted here.

In the transistor 161 including the n⁺ layers 113a and 113b, the amount of change in on-state current (Ion deterioration) between before and after application of a negative gate stress in a BT test can be suppressed.

This embodiment can be freely combined with Embodiment 2 or 5.

### Embodiment 7

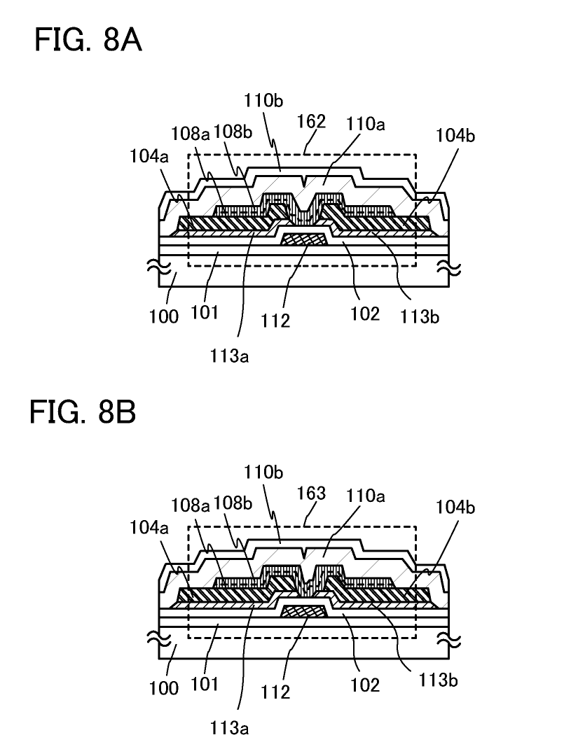

In this embodiment, an example of a structure which is partly different from that described in Embodiment 3 will be described with reference to FIGS. 8A and 8B. Note that in FIGS. 8A and 8B, the same reference numerals are used for the same parts as those in FIGS. 3A to 3F, and description of the parts with the same reference numerals is omitted here.

FIG. 8A is a cross-sectional view of a bottom-gate transistor 162. The transistor 162 includes, over the substrate 100 having an insulating surface, the oxide insulating layer 101, the gate electrode layer 112, the gate insulating layer 102, the n⁺ layers 113a and 113b, the source electrode layer 104a, the drain electrode layer 104b, the stack of oxide semiconductor layers including a channel formation region, and the oxide insulating film 110a. The stack of oxide semiconductor layers (the stacked layer of the first crystalline oxide semiconductor layer 108a and the second crystalline oxide semiconductor layer 108b) is provided to cover the source electrode layer 104a and the drain electrode layer 104b. A region functioning as a channel formation region is part of the stack of oxide semiconductor layers overlapping with the gate electrode layer 112 with the gate insulating layer 102 interposed therebetween.

In addition, the protective insulating film 110b is provided to cover the oxide insulating film 110a.

A manufacturing process of the transistor 162 is the same as that of the transistor illustrated in FIG. 3F, except for a step in which the n⁺ layers 113a and 113b are provided. The step different from that in FIGS. 3A to 3F is described below.

The following steps are the same as those of the transistor in FIG. 3F: forming the oxide insulating layer 101 over the substrate 100; forming a conductive film and being subjected to a photolithography step, so that the gate electrode layer 112 is formed; and forming the gate insulating layer 102 over the gate electrode layer 112.

After the gate insulating layer 102 is formed, using an In—Zn—O-based material, an In—Sn—O-based material, an In—O-based material, or a Sn—O-based material, a film functioning as an n⁺ layer is formed to a thickness greater than or equal to 1 nm and less than or equal to 10 nm. In addition, SiO₂ may be contained in the above material for the n⁺ layer. In this embodiment, an In—Zn—O film is formed to a thickness of 5 nm.

Next, a conductive film for forming the source electrode layer and the drain electrode layer is formed and processed, so that the source electrode layer 104a and the drain electrode layer 104b are formed.

Then, the film functioning as an n⁺ layer is processed, so that the n⁺ layer 113a is formed to be protruded from the source electrode layer 104a and the n⁺ layer 113b is formed to be protruded from the drain electrode layer 104b. Thus, the channel length of the transistor illustrated in FIG. 8A is determined by a distance between the n⁺ layer 113a and the n⁺ layer 113b. On the other hand, the channel length of the transistor illustrated in FIG. 3F is determined by the distance between the source electrode layer 104a and the drain electrode layer 104b.

Next, a first oxide semiconductor film is formed to a thickness greater than or equal to 1 nm and less than or equal to 10 nm over the source electrode layer 104a and the drain electrode layer 104b. Since the subsequent steps are the same as those in Embodiment 3, the detailed description is omitted here.

In the transistor 162 including the n⁺ layers 113a and 113b, the amount of change in on-state current (Ion deterioration) between before and after application of a negative gate stress in a BT test can be suppressed.

FIG. 8B illustrates an example of a transistor 163 in which by processing of the film functioning as an n⁺ layer, the length in the channel length direction of the n⁺ layer 113a which is protruded from the source electrode layer 104a is different from the length in the channel length direction of the n⁺ layer 113b which is protruded from the drain electrode layer 104b. In the transistor 163, the length in the channel length direction of the n⁺ layer 113b is larger than that of the n⁺ layer 113a. Thus, the channel length is reduced, whereby high-speed operation is achieved. In addition, the distance between the source electrode layer 104a and the drain electrode layer 104b is increased, whereby short circuit is prevented.

This embodiment can be freely combined with Embodiment 3 or 5.

### Embodiment 8

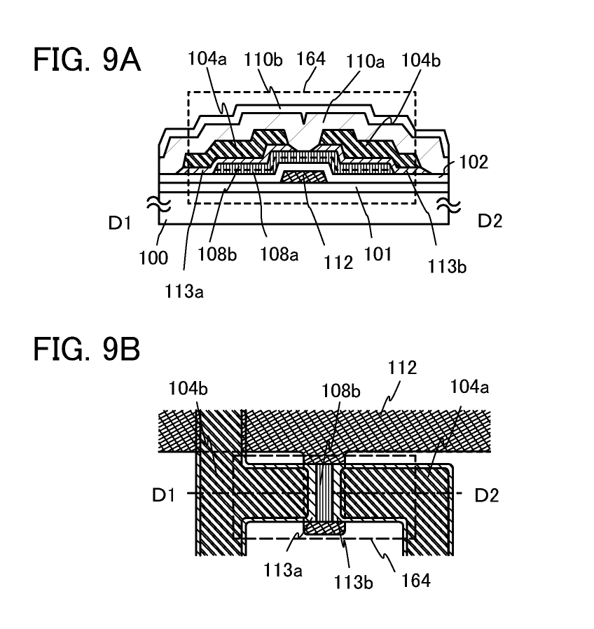

In this embodiment, an example of a structure which is partly different from that described in Embodiment 4 will be described with reference to FIGS. 9A and 9B. Note that in FIGS. 9A and 9B, the same reference numerals are used for the same parts as those in FIGS. 4A to 4E, and description of the parts with the same reference numerals is omitted here.

FIG. 9B is a top view of a bottom-gate transistor 164. FIG. 9A is a cross-sectional view illustrating a cross-sectional structure of the bottom-gate transistor 164 along a dashed line D1-D2 in FIG. 9B which is a top view. The transistor 164 includes, over the substrate 100 having an insulating surface, the oxide insulating layer 101, the gate electrode layer 112, the gate insulating layer 102, the stack of oxide semiconductor layers including a channel formation region, the n⁺ layers 113a and 113b, the source electrode layer 104a, the drain electrode layer 104b, and the oxide insulating film 110a. The source electrode layer 104a and the drain electrode layer 104b are provided over the stack of oxide semiconductor layers (the stacked layer of the first crystalline oxide semiconductor layer 108a and the second crystalline oxide semiconductor layer 108b). Part of a region in the stack of oxide semiconductor layers overlapping with the gate electrode layer 112 with the gate insulating layer 102 interposed therebetween functions as a channel formation region.

In addition, the protective insulating film 110b is provided to cover the oxide insulating film 110a.

A manufacturing process of the transistor 164 is the same as that of the transistor illustrated in FIG. 4E except for a step in which the n⁺ layers 113a and 113b are provided. The step different from that in FIGS. 4A to 4E is described below.

The structure illustrated in FIG. 4D is formed through the manufacturing steps described in Embodiment 4.

Next, using an In—Zn—O-based material, an In—Sn—O-based material, an In—O-based material, or a Sn—O-based material, a film functioning as an n⁺ layer is formed to a thickness greater than or equal to 1 nm and less than or equal to 10 nm. In addition, SiO₂ may be contained in the above material for the n⁺ layer. In this embodiment, an In—Sn—O film is formed to a thickness of 5 nm.

Next, a conductive film for forming the source electrode layer and the drain electrode layer is formed and processed to form the source electrode layer 104a and the drain electrode layer 104b.

Next, with use of the source electrode layer 104a and the drain electrode layer 104b as a mask, the film functioning as an n⁺ layer is processed, so that the n⁺ layer 113a is formed to have a tapered portion protruded from the source electrode layer 104a and the n⁺ layer 113b is formed to have a tapered portion protruded from the drain electrode layer 104b. The channel length of the transistor 164 illustrated in FIG. 9A is determined by a distance between the n⁺ layer 113a and the n⁺ layer 113b. On the other hand, the channel length of the transistor illustrated in FIG. 4E is determined by a distance between the source electrode layer 104a and the drain electrode layer 104b.

Note that the taper angle (an angle formed between a side surface of the n⁺ layer 113a and a plan surface of the substrate 100) of the tapered portion is less than or equal to 30°.

The subsequent steps are the same as those in Embodiment 4. The insulating films 110a and 110b which cover the stack of oxide semiconductor layers, the source electrode layer 104a and the drain electrode layer 104b are formed.

Through the above process, the bottom-gate transistor 164 is formed.

When the n⁺ layer 113a or 113b is formed between the stack of oxide semiconductor layers and the source electrode layer 104a or the drain electrode layer 104b, the contact resistance can be lower than the contact resistance in the case where the stack of oxide semiconductor layers is in contact with the source electrode layer 104a or the drain electrode layer 104b. In addition, when the n⁺ layers 113a and 113b are formed, the parasitic capacitance can be reduced, and the amount of change in on-state current (Ion deterioration) between before and after application of a negative gate stress in a BT test can be suppressed.

This embodiment can be freely combined with Embodiment 4 or 5.

### Embodiment 9)

In this embodiment, an example of a semiconductor device having a novel structure will be described. In this semiconductor device, the transistor including the stack of oxide semiconductor layers described in any of Embodiments 1 to 8 is used, stored data can be retained even in a state where no power is supplied, and there is no limitation on the number of writing operations.

Since the off-state current of the transistor described in any of Embodiments 1 to 8 is low, the stored data can be retained for an extremely long time owing to such a transistor. In other words, power consumption can be adequately reduced because refresh operation is not needed or the frequency of refresh operation can be extremely low. Moreover, the stored data can be retained for a long time even when power is not supplied.

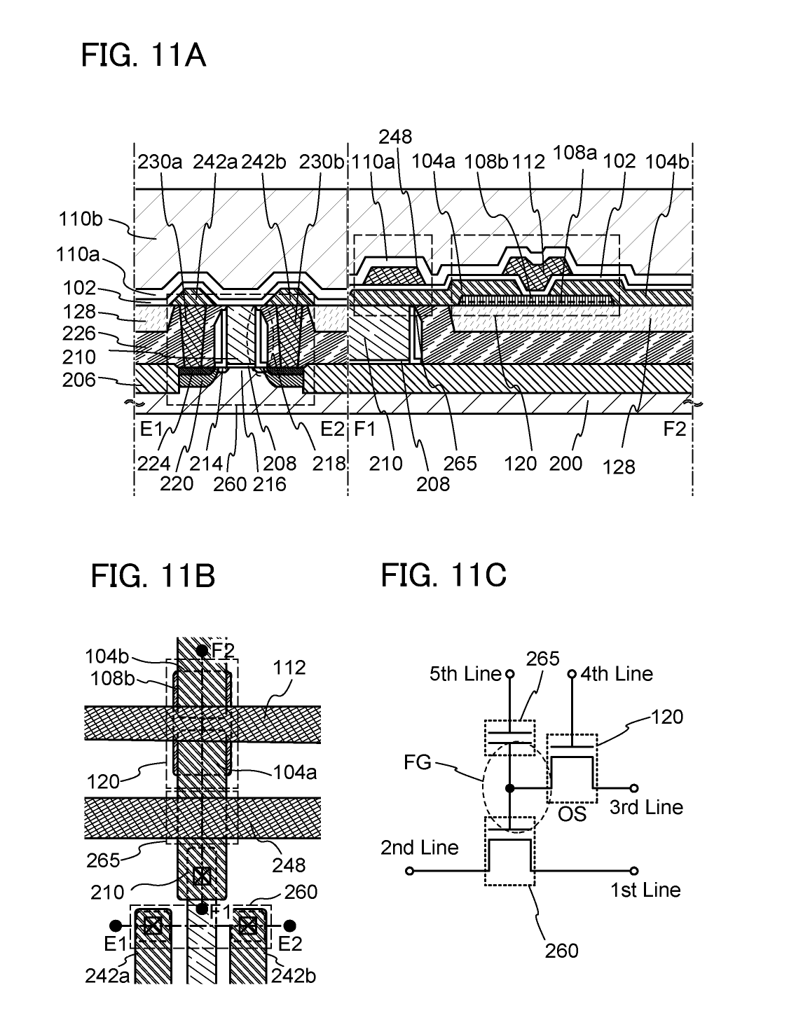

FIGS. 11A to 11C illustrate an example of a structure of a semiconductor device. FIG. 11A is a cross-sectional view of the semiconductor device, and FIG. 11B is a plan view of the semiconductor device. Here, FIG. 11A corresponds to a cross section along line E1-E2 and line F1-F2 in FIG. 11B. The semiconductor device illustrated in FIGS. 11A and 11B includes a transistor 260 including a material other than an oxide semiconductor in a lower portion, and a transistor 120 including an oxide semiconductor in an upper portion. The transistor 120 is the same as that in Embodiment 1; thus, for description of FIGS. 11A to 11C, the same reference numerals are used for the same parts as those in FIG. 1E.

The transistor 260 includes: a channel formation region 216 in a substrate 200 containing a semiconductor material (e.g., silicon or the like); impurity regions 214 and high-concentration impurity regions 220 (which are collectively called simply impurity regions and which are provided so that the channel formation region 216 is sandwiched therebetween); a gate insulating layer 208 over the channel formation region 216; a gate electrode layer 210 over the gate insulating layer 208; a source or drain electrode layer 230a electrically connected to the impurity region; and a source or drain electrode layer 230b electrically connected to the impurity region.

Here, sidewall insulating layers 218 are formed on side surfaces of the gate electrode layer 210. The high-concentration impurity regions 220 are provided in regions of the substrate 200 which do not overlap with the sidewall insulating layers 218 when seen from a direction perpendicular to a main surface of the substrate 200. Metal compound regions 224 are provided in contact with the high-concentration impurity regions 220. An element isolation insulating layer 206 is provided over the substrate 200 so as to surround the transistor 260. An interlayer insulating layer 226 and an interlayer insulating layer 128 are provided so as to cover the transistor 260. The source or drain electrode layer 230a and the source or drain electrode layer 230b are electrically connected to the metal compound regions 224 through openings formed in the interlayer insulating layers 226 and 128. In other words, the source or drain electrode layer 230a and the source or drain electrode layer 230b are electrically connected to the high-concentration impurity regions 220 and the impurity regions 214 through the metal compound regions 224. Note that the sidewall insulating layer 218 is not formed in some cases for integration of the transistor 260 or the like.

The transistor 120 illustrated in FIGS. 11A to 11C includes the first crystalline oxide semiconductor layer 108a, the second crystalline oxide semiconductor layer 108b, the source electrode layer 104a, the drain electrode layer 104b, the gate insulating layer 102, and the gate electrode layer 112. The transistor 120 can be formed by the process described in Embodiment 1.

In FIGS. 11A to 11C, the first crystalline oxide semiconductor layer 108a can have a uniform thickness by improving the planarity of the interlayer insulating layer 128 over which the first crystalline oxide semiconductor layer 108a is formed; thus, the characteristics of the transistor 120 can be improved. Note that the channel length is small, for example, 0.8 μm or 3 μm. Further, the interlayer insulating layer 128 corresponds to the oxide insulating layer 101 and is formed using the same material.

A capacitor 265 illustrated in FIGS. 11A to 11C includes the source electrode layer 104a, the gate insulating layer 102, and an electrode 248.

The oxide insulating film 110a is provided over the transistor 120 and the capacitor 265. Over the oxide insulating film 110a, the protective insulating film 110b is provided.

Wirings 242a and 242b which are formed in the same step as the source electrode layer 104a and the drain electrode layer 104b are provided. The wiring 242a is electrically connected to the source or drain electrode layer 230a, and the wiring 242b is electrically connected to the source or drain electrode layer 230b.

FIG. 11C shows a circuit configuration. Note that in the circuit diagram, in some cases, “OS” is written beside a transistor in order to indicate that the transistor includes an oxide semiconductor.

In FIG. 11C, a first wiring (a 1st Line) is electrically connected to the source electrode layer of the transistor 260, and a second wiring (a 2nd Line) is electrically connected to a drain electrode layer of the transistor 260. A third wiring (a 3rd line) and one of the source electrode layer and the drain electrode layer of the transistor 120 are electrically connected to each other, and a fourth wiring (a 4th line) and a gate electrode layer of the transistor 120 are electrically connected to each other. A gate electrode layer of the transistor 260, the other of the source electrode layer and the drain electrode layer of the transistor 120, and one electrode of the capacitor 265 are electrically connected to one another. Further, a fifth wiring (a 5th line) and the other electrode of the capacitor 265 are electrically connected to each other.

The semiconductor device in FIG. 11C can write, hold, and read data as described below, utilizing a characteristic in which the potential of the gate electrode layer of the transistor 260 can be held.

Firstly, writing and holding of data will be described. The potential of the fourth wiring is set to a potential at which the transistor 120 is turned on, whereby the transistor 120 is turned on. Thus, the potential of the third wiring is applied to the gate electrode layer of the transistor 260 and the capacitor 265. In other words, a predetermined charge is supplied to the gate electrode layer of the transistor 260 (i.e., writing of data). Here, charge for supply of a potential level or charge for supply of a different potential level (hereinafter referred to as Low level charge and High level charge) is given. After that, the potential of the fourth wiring is set to a potential at which the transistor 120 is turned off, so that the transistor 120 is turned off. Thus, the charge given to the gate electrode layer of the transistor 260 is held (storing).

The off-state current of the transistor 120 is extremely low. Specifically, the value of the off-state current (here, current per micrometer of channel width) is less than or equal to 100 zA/μm (1 zA (zeptoampere) is 1×10⁻²¹ A), preferably less than or equal to 10 zA/μm. Thus, the charge of the gate electrode layer in the transistor 260 can be retained for a long time.

As the substrate 200, a semiconductor substrate called an SOI (silicon on insulator) substrate can be used. Alternatively, as the substrate 200, a substrate in which an SOI layer is formed over an insulating substrate such as a glass substrate may be used. As an example of a formation method of an SOI substrate in which an SOI layer is formed over a glass substrate, there is a method in which a thin single crystal layer is formed over a glass substrate by a hydrogen ion implantation separation method. Specifically, by irradiation with H₃⁺ ions using an ion doping apparatus, a separation layer is formed in a silicon substrate at a predetermined depth from a surface, a glass substrate having an insulating layer on its surface is bonded to the surface of the silicon substrate by being pressed, and a heat treatment is performed at a temperature which is lower than a temperature at which separation occurs in the separation layer or at an interface of the separation layer. Alternatively, the heating temperature may be a temperature at which the separation layer is embrittled. As a result, part of the semiconductor substrate is separated from the silicon substrate by generating a separation border in the separation layer or at an interface of the separation layer, so that the SOI layer is formed over the glass substrate.

This embodiment can be freely combined with any one of Embodiments 1 to 8.

### Embodiment 10

In this embodiment, an example in which at least part of a driver circuit and a transistor to be disposed in a pixel portion are formed over one substrate will be described below.

The transistor to be disposed in the pixel portion is formed according to any one of Embodiments 1 to 8. Further, the transistor described in any of Embodiments 1 to 8 is an n-channel TFT, and thus a part of a driver circuit that can be formed using n-channel TFTs among driver circuits is formed over the same substrate as the transistor of the pixel portion.

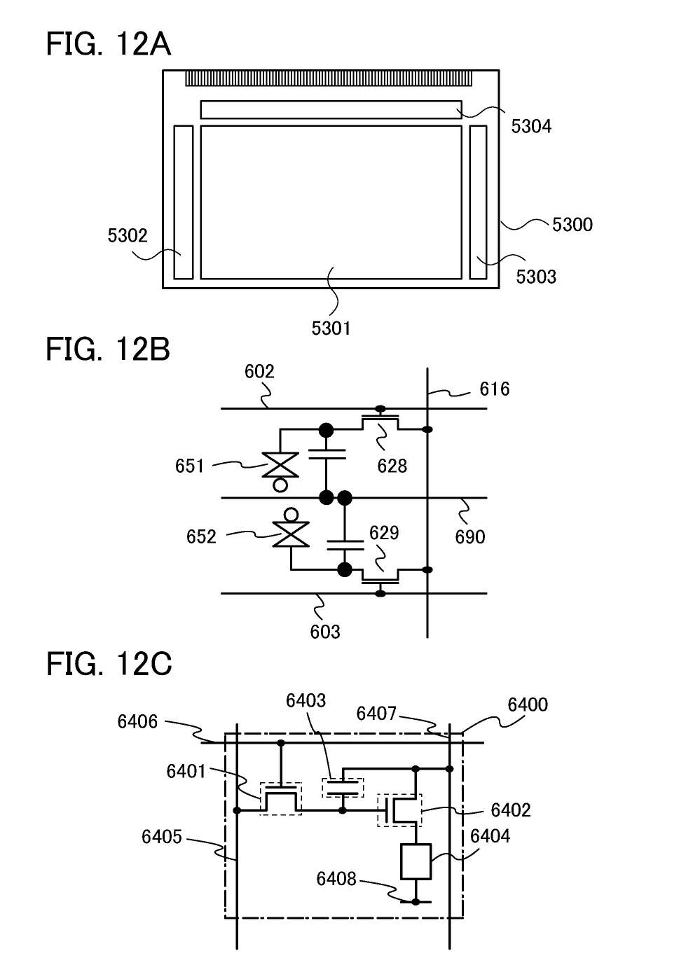

FIG. 12A illustrates an example of a block diagram of an active matrix display device. A pixel portion 5301, a first scan line driver circuit 5302, a second scan line driver circuit 5303, and a signal line driver circuit 5304 are formed over a substrate 5300 of the display device. In the pixel portion 5301, a plurality of signal lines extended from the signal line driver circuit 5304 are arranged and a plurality of scan lines extended from the first scan line driver circuit 5302 and the second scan line driver circuit 5303 are arranged. Note that pixels which include display elements are provided in a matrix in respective regions where the scan lines and the signal lines intersect with each other. Further, the substrate 5300 in the display device is connected to a timing control circuit (also referred to as a controller or a controller IC) through a connection point such as a flexible printed circuit (FPC).

In FIG. 12A, the first scan line driver circuit 5302, the second scan line driver circuit 5303, and the signal line driver circuit 5304 are formed over the same substrate 5300 as the pixel portion 5301. Accordingly, the number of components of a drive circuit which is provided outside and the like are reduced, so that reduction in cost can be achieved. Further, if the driver circuit is provided outside the substrate 5300, wiring would need to be extended and the number of wiring connections would be increased. However, if the driver circuit is provided over the substrate 5300, the number of wiring connections can be reduced. Consequently, improvement in reliability and yield can be achieved.

FIG. 12B illustrates an example of a circuit configuration of the pixel portion. Here, a pixel structure of a VA liquid crystal display panel is shown.

In this pixel structure, a plurality of pixel electrode layers are provided in one pixel, and transistors are connected to respective pixel electrode layers. The plurality of transistors are constructed so as to be driven by different gate signals. In other words, signals applied to individual pixel electrode layers in a multi-domain pixel are controlled independently.

The gate wiring 602 of the transistor 628 and a gate wiring 603 of the transistor 629 are separated so that different gate signals can be given thereto. In contrast, the source or the drain electrode layer 616 functioning as a data line is used in common for the transistors 628 and 629. As each of the transistors 628 and 629, any of the transistors described in Embodiments 1 to 8 can be used as appropriate.

A first pixel electrode layer and a second pixel electrode layer have different shapes and are separated by a slit. The second pixel electrode layer is provided so as to surround the external side of the first pixel electrode layer which is spread in a V shape. Timing of voltage application is made to vary between the first and second pixel electrode layers by the transistors 628 and 629 in order to control alignment of the liquid crystal. The transistor 628 is connected to the gate wiring 602, and the transistor 629 is connected to the gate wiring 603. When different gate signals are supplied to the gate wiring 602 and the gate wiring 603, operation timings of the thin film transistor 628 and the thin film transistor 629 can be varied.

Further, a storage capacitor is formed using a capacitor wiring 690, a gate insulating layer as a dielectric, and a capacitor electrode electrically connected to the first pixel electrode layer or the second pixel electrode layer.

The first pixel electrode layer, a liquid crystal layer, and a counter electrode layer overlap with each other to form a first liquid crystal element 651. The second pixel electrode layer, a liquid crystal layer, and a counter electrode layer overlap with each other to form a second liquid crystal element 652. The pixel structure is a multi-domain structure in which the first liquid crystal element 651 and the second liquid crystal element 652 are provided in one pixel.

Note that the pixel structure is not limited to that illustrated in FIG. 12B. For example, a switch, a resistor, a capacitor, a transistor, a sensor a logic circuit, or the like may be added to the pixel illustrated in FIG. 12B.

FIG. 12C shows an example of a circuit configuration of the pixel portion. Here, a pixel structure of a display panel using an organic EL element is shown.

In an organic EL element, by application of voltage to a light-emitting element, electrons and holes are separately injected from a pair of electrodes into a layer containing a light-emitting organic compound, and current flows. The carriers (electrons and holes) are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 12C shows an example of a pixel structure to which digital time grayscale driving can be applied, as an example of a semiconductor device.

A structure and operation of a pixel to which digital time grayscale driving can be applied are described. Here, one pixel includes two n-channel transistors each of which includes an oxide semiconductor layer as a channel formation region.

A pixel 6400 includes a switching transistor 6401, a driver transistor 6402, a light-emitting element 6404, and a capacitor 6403. A gate electrode layer of the switching transistor 6401 is connected to a scan line 6406, a first electrode (one of a source electrode layer and a drain electrode layer) of the switching transistor 6401 is connected to a signal line 6405, and a second electrode (the other of the source electrode layer and the drain electrode layer) of the switching transistor 6401 is connected to a gate electrode layer of the driver transistor 6402. The gate electrode layer of the driving transistor 6402 is connected to a power supply line 6407 through the capacitor 6403, a first electrode of the driving transistor 6402 is connected to the power supply line 6407, and a second electrode of the driving transistor 6402 is connected to a first electrode (a pixel electrode) of the light-emitting element 6404. A second electrode of the light-emitting element 6404 corresponds to a common electrode 6408. The common electrode 6408 is electrically connected to a common potential line provided over the same substrate.

The second electrode (common electrode 6408) of the light-emitting element 6404 is set to a low power supply potential. Note that the low power supply potential is a potential that is lower than a high power supply potential with reference to the high power supply potential that is set to the power supply line 6407. As the low power supply potential, GND, 0 V, or the like may be employed, for example. A potential difference between the high power supply potential and the low power supply potential is applied to the light-emitting element 6404 and current is supplied to the light-emitting element 6404, so that the light-emitting element 6404 emits light. Here, in order to make the light-emitting element 6404 emit light, each potential is set so that the potential difference between the high power supply potential and the low power supply potential is a forward threshold voltage or higher of the light-emitting element 6404.

Note that gate capacitance of the driver transistor 6402 may be used as capacitance of the capacitor, so that the capacitor 6403 can be omitted. The gate capacitance of the driving transistor 6402 may be formed between the channel formation region and the gate electrode layer.

In the case of voltage-input voltage-driving method, a video signal is input to the gate electrode layer of the driving transistor 6402 so that the driving transistor 6402 is in either of two states of being sufficiently turned on and turned off. That is, the driving transistor 6402 operates in a linear region, and thus, voltage higher than the voltage of the power supply line 6407 is applied to the gate electrode layer of the driving transistor 6402. Note that a voltage higher than or equal to the sum of the voltage of the power supply line and Vth of the driver transistor 6402 is applied to the signal line 6405.

In the case of performing analog grayscale driving instead of digital time grayscale driving, the same pixel configuration as FIG. 12C can be employed by inputting signals in a different way.

In the case of performing analog grayscale driving, a voltage greater than or equal to the sum of the forward voltage of the light-emitting element 6404 and Vth of the driving transistor 6402 is applied to the gate electrode layer of the driving transistor 6402. The forward voltage of the light-emitting element 6404 indicates a voltage at which a desired luminance is obtained, and includes at least the forward threshold voltage. The video signal by which the driver transistor 6402 operates in a saturation region is input, so that current can be supplied to the light-emitting element 6404. In order for the driver transistor 6402 to operate in the saturation region, the potential of the power supply line 6407 is set higher than the gate potential of the driver transistor 6402. When an analog video signal is used, it is possible to feed current to the light-emitting element 6404 in accordance with the video signal and perform analog grayscale driving.

Note that the pixel configuration is not limited to that illustrated in FIG. 12C. For example, a switch, a resistor, a capacitor, a sensor, a transistor, a logic circuit, or the like may be added to the pixel illustrated in FIG. 12C.

### Embodiment 11

A semiconductor device disclosed in this specification can be applied to a variety of electronic devices (including game machines). Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like. Examples of electronic devices each including the display device described in any of the above embodiments will be described.

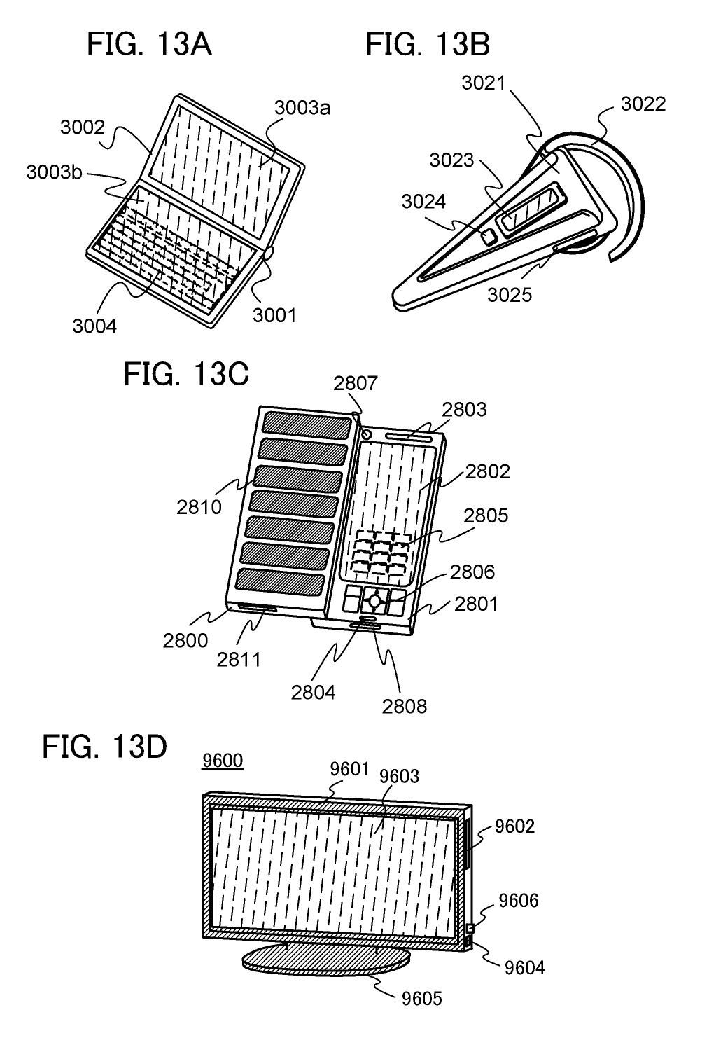

FIG. 13A illustrates a portable information terminal, which includes s main body 3001, a housing 3002, display portions 3003a and 3003b, and the like. The display portion 3003b functions as a touch panel. By touching a keyboard 3004 displayed on the display portion 3003b, a screen can be operated, and text can be input. Needless to say, the display portion 3003a may functions as a touch panel. A liquid crystal panel or an organic light-emitting panel is manufactured by using the semiconductor device described in Embodiment 4 as a switching element and applied to the display portion 3003a or 3003b, whereby a highly reliable portable information terminal can be provided.

The portable information terminal illustrated in FIG. 13A has a function of displaying various kinds of information (e.g., a still image, a moving image, and a text image) on the display portion, a function of displaying a calendar, a data, the time, or the like on the display portion, a function of operating or editing the information displayed on the display portion, a function of controlling processing by various kinds of software (programs), and the like. Furthermore, an external connection terminal (an earphone terminal, a USB terminal, or the like), a recording medium insertion portion, and the like may be provided on the back surface or the side surface of the housing.

The portable information terminal illustrated in FIG. 13A may transmit and receive data wirelessly. Through wireless communication, desired book data or the like can be purchased and downloaded from an electronic book server.

FIG. 13B illustrates a portable music player, which includes, in a main body 3021, a display portion 3023, a fixing portion 3022 with which the main body is worn on the ear, a speaker, an operation button 3024, an external memory slot 3025, and the like. A liquid crystal panel or an organic light-emitting panel is manufactured by using the semiconductor device described in Embodiment 4 as a switching element and applied to the display portion 3023, whereby a highly reliable portable music player (PDA) can be provided.

Furthermore, when the portable music player illustrated in FIG. 13B functions as an antenna, a microphone, or a wireless communication device and is used with the mobile phone, a user can talk wirelessly (so-called hands free) while driving a car or the like.

FIG. 13C illustrates a mobile phone, which includes two housings, a housing 2800 and a housing 2801. The housing 2801 includes a display panel 2802, a speaker 2803, a microphone 2804, a pointing device 2806, a camera lens 2807, an external connection terminal 2808, and the like. In addition, the housing 2800 includes a solar cell 2810 having a function of charge of the portable information terminal, an external memory slot 2811, and the like. Further, an antenna is incorporated in the housing 2801. The semiconductor device described in Embodiment 4 is applied to the display panel 2802, whereby a highly reliable mobile phone can be provided.

Further, the display panel 2802 includes a touch panel. A plurality of operation keys 2805 which are displayed as images are indicated by dashed lines in FIG. 13C. Note that a boosting circuit by which a voltage output from the solar cell 2810 is increased to be sufficiently high for each circuit is also included.

In the display panel 2802, the display direction can be appropriately changed depending on a usage pattern. Further, the display device is provided with the camera lens 2807 on the same surface as the display panel 2802, and thus it can be used as a video phone. The speaker 2803 and the microphone 2804 can be used for videophone calls, recording and playing sound, and the like as well as voice calls. Furthermore, the housings 2800 and 2801 which are developed as illustrated in FIG. 13C can overlap with each other by sliding; thus, the size of the mobile phone can be decreased, which makes the mobile phone suitable for being carried.

The external connection terminal 2808 can be connected to an AC adapter and various types of cables such as a USB cable, and charging and data communication with a personal computer are possible. Moreover, a large amount of data can be stored by inserting a storage medium into the external memory slot 2811 and can be moved.

Further, in addition to the above functions, an infrared communication function, a television reception function, or the like may be provided.

FIG. 13D illustrates an example of a television device. In a television set 9600, a display portion 9603 is incorporated in a housing 9601. The display portion 9603 can display images. Here, the housing 9601 is supported on a stand 9605 provided with a CPU. When the semiconductor device described in Embodiment 4 is applied to the display portion 9603, the television set 9600 can have high reliability.

The television set 9600 can be operated with an operation switch of the housing 9601 or a separate remote controller. Further, the remote controller may be provided with a display portion for displaying data output from the remote controller.

Note that the television set 9600 is provided with a receiver, a modem, and the like. With use of the receiver, general television broadcasting can be received. Moreover, when the display device is connected to a communication network with or without wires via the modem, one-way (from a sender to a receiver) or two-way (between a sender and a receiver or between receivers) information communication can be performed.

Further, the television set 9600 is provided with an external connection terminal 9604, a storage medium recording and reproducing portion 9602, and an external memory slot. The external connection terminal 9604 can be connected to various types of cables such as a USB cable, and data communication with a personal computer is possible. A disk storage medium is inserted into the storage medium recording and reproducing portion 9602, and reading data stored in the storage medium and writing data to the storage medium can be performed. In addition, a picture, a video, or the like stored as data in an external memory 9606 inserted to the external memory slot can be displayed on the display portion 9603.

When the semiconductor device described in Embodiment 9 is applied to the external memory 9606 or a CPU, the television set 9600 can have high reliability and power consumption thereof is sufficiently reduced.

The methods and structures described in this embodiment can be combined as appropriate with any of the methods and structures described in the other embodiments.

### Example 1

In this example, evaluation results of characteristics of a transistor manufactured by a manufacturing method described in Embodiment 4 will be described.

In this example, transistors each having a channel length L of 3 μm and a channel width W of 50 μm were formed over one substrate, and the transistor characteristics were evaluated. First, a method for manufacturing a transistor used for measurement is described.

First, a 100-nm-thick silicon oxynitride film was formed as a base film over a glass substrate by a CVD method, and a 150-nm-thick tungsten film was formed as a gate electrode layer over the silicon oxynitride film by a sputtering method. The tungsten film was etched selectively, thereby forming the gate electrode layer.

Then, as a gate insulating layer, a silicon oxynitride film (∈=4.1) with a thickness of 100 nm was formed over the gate electrode layer by a CVD method.

Next, a first oxide semiconductor layer with a thickness of 5 nm was formed over the gate insulating layer using an In—Ga—Zn—O-based oxide semiconductor target (In₂O₃:Ga₂O₃:ZnO=1:1:2 (molar ratio)) in an atmosphere containing argon and oxygen (argon:oxygen=30 sccm:15 sccm) under the following conditions: the distance between the substrate and the target was 60 mm, the pressure was 0.4 Pa, the direct current (DC) power supply was 0.5 kW, and the substrate temperature was 400° C.

Next, a first heat treatment was performed on the first oxide semiconductor layer at 450° C. in a nitrogen atmosphere for an hour.

Next, a second oxide semiconductor layer with a thickness of 25 nm was formed over the first oxide semicondutor layer using an In—Ga—Zn—O-based oxide semiconductor target (In₂O₃:Ga₂O₃:ZnO=1:1:2 (molar ratio)) in an atmosphere containing argon and oxygen (argon:oxygen=30 sccm:15 sccm) under the following conditions: the distance between the substrate and the target was 60 mm, the pressure was 0.4 Pa, the direct current (DC) power supply was 0.5 kW, and the substrate temperature was 400° C.

Next, a second heat treatment was performed on the second oxide semiconductor layer at 450° C. for an hour in a dry air atmosphere.

Next, a titanium film (with a thickness of 150 nm) was formed as source and drain electrode layers over the oxide semiconductor layer by a sputtering method at room temperature (25° C.). The source and drain electrode layers were selectively etched, so that the length in the channel direction of the source electrode layer overlapping with the gate electrode layer with the gate insulating layer interposed therebetween was 3 μm, and the length in the channel direction of the drain electrode layer overlapping with the gate electrode layer with the gate insulating layer interposed therebetween was 3 μm.

Next, a silicon oxide film with a thickness of 300 nm was formed at 100° C. as a protective insulating layer by a sputtering method so as to be in contact with the oxide semiconductor layer. The silicon oxide film functioning as a protective layer was etched selectively, whereby openings were formed over the gate electrode layer and the source and drain electrode layers.

Next, as an electrode layer for measurement, an In—Sn—O film (with a thickness of 110 nm) containing SiO₂ was formed by a sputtering method in an atmosphere containing argon and oxygen (argon:oxygen=50 sccm:1.5 sccm), at room temperature (25° C.). The electrode layer for measurement was etched selectively, so that an electrode layer for measurement which was electrically connected to the gate electrode layer through the opening, an electrode layer for measurement which was electrically connected to the source electrode layer through the opening, and an electrode layer for measurement which was electrically connected to the drain electrode layer through the opening were formed. After that, a third heat treatment was performed at 250° C. for an hour in a nitrogen atmosphere.

Through the above steps, as Sample 1, a plurality of transistors each having the channel width W of 50 μm and the channel length L of 3 μm were manufactured over one substrate.

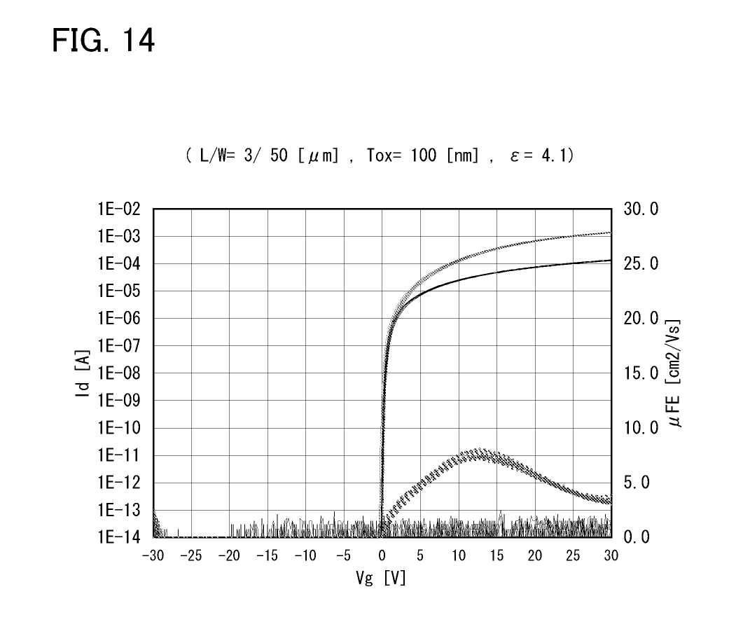

Then, the current vs. voltage characteristics of ten transistors of Sample 1 were measured. The substrate temperature at the measurement was room temperature (25° C.). FIG. 14 shows Vg-Id curves which show a change in current flowing between a source electrode layer and a drain electrode layer (hereinafter, referred to as drain current or Id) with respect to a change in voltage between the source electrode layer and a gate electrode layer (hereinafter, referred to as gate voltage or Vg) of the transistor. The horizontal axis represents the gate voltage on a linear scale and the vertical axis represents the drain current on a logarithmic scale.

The measurement results of the current vs. voltage characteristics are shown in FIG. 14 are the results obtained by setting the voltage between the source electrode layer and the drain electrode layer to 1 V and changing the gate voltage from −30 V to 30 V and the results obtained by setting the voltage between the source electrode layer and the drain electrode layer to 10 V and changing the gate voltage from −30 V to 30 V.

Note that the measured field-effect mobility shown in FIG. 14 is obtained in the case where the voltage between the source electrode layer and the drain electrode layer was 10 V.

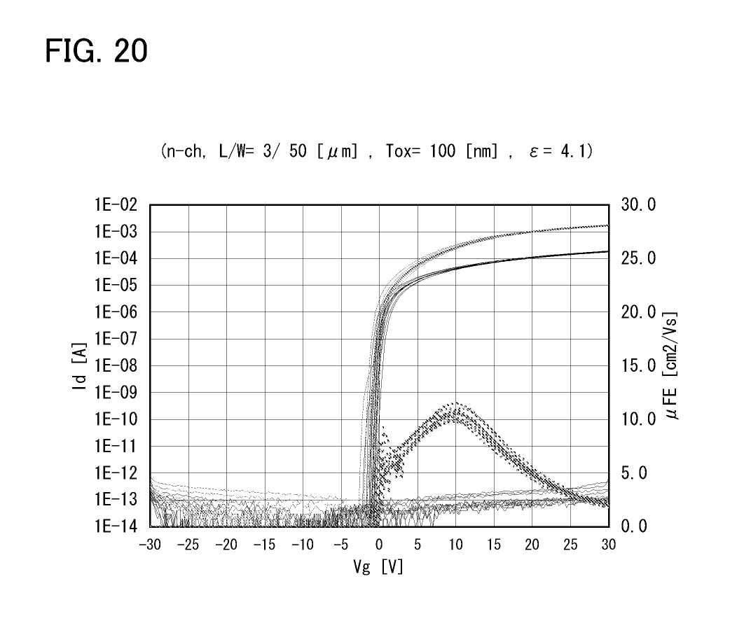

FIG. 20 shows measurement results of a comparison example. As a comparison example, transistors of Sample A were manufactured, and the current vs. voltage characteristics of ten transistors were measured as in the case of FIG. 14. The measurement results thereof are shown in FIG. 20. Note that a manufacturing process of Sample A is partially different from that of Sample 1. The manufacturing process of Sample A is described. An oxide semiconductor layer was formed to a thickness of 25 nm over the gate insulating layer using an In—Ga—Zn—O based oxide semiconductor target (In₂O₃:Ga₂O₃:ZnO=1:1:2 (molar ratio)) in an atmosphere containing argon and oxygen (argon:oxygen=30 sccm:15 sccm) under the following conditions: the distance between the substrate and the target was 60 mm, the pressure was 0.4 Pa, the direct current (DC) power supply was 0.5 kW, and the substrate temperature was 200° C. Next, a first heat treatment was performed on the oxide semiconductor layer at 450° C. for an hour in a dry air atmosphere. Then, as in Sample 1, a source electrode layer and a drain electrode layer were formed over the oxide semiconductor layer, and the following steps are same as those of Sample 1.

As compared to FIG. 20, FIG. 14 shows that variation in the current vs. voltage characteristics of the ten transistors is small, which is favorable. From the obtained Vg-Id curves, the threshold voltages (hereinafter, referred to as threshold value or Vth) were obtained. In FIG. 14, the threshold value of Sample 1 was 2.15 V. In FIG. 20, the threshold value of Sample A was 1.44 V.

In the Vg-Id characteristics, when the Vg-Id curve at the sweep from −30 V to +30 V is compared to the Vg-Id curve at the sweep from +30 V to −30 V, there is a particularly large difference (Δshift) in a rising portion of the Vg-Id curves. The transistor characteristics in such a rising portion are important particularly in a device which is greatly affected by the value of off-state current. The shift value, which is one characteristic value of the transistor in a rising portion, means a voltage value at a rising of the Vg-Id curve and corresponds to a voltage at a drain-source current (Id) which is lower than or equal to 1×10⁻¹² A. In FIG. 14, the shift value of Sample 1 was −0.4 V. In FIG. 20, the shift value of Sample A was −0.02 V.

Then, a BT test was performed on the transistors of Sample 1 and Sample A manufactured in this example. The BT test is one kind of accelerated test and can evaluate change in characteristics, caused by long-term usage of transistors, in a short time. In particular, the amount of change in threshold voltage of the transistor between before and after performance of the BT test is an important indicator for examining reliability. As a difference in the threshold voltage between before and after performance of the BT test is small, the transistor has higher reliability.

Specifically, the temperature of a substrate (substrate temperature) over which a transistor is formed is set at fixed temperature, a source electrode layer and a drain electrode layer of the transistor are set at the same potential, and a gate electrode layer is supplied with potential different from that of the source electrode layer and the drain electrode layer for a certain period. The substrate temperature may be determined as appropriate in accordance with the test purpose. A BT test in which a potential applied to a gate electrode layer is higher than the potential of a source electrode layer and a drain electrode layer is referred to as +BT test and a BT test in which a potential applied to a gate electrode layer is lower than the potential of a source electrode layer and a drain electrode layer is referred to as −BT test.

The stress conditions for the BT test can be determined in accordance with the substrate temperature, intensity of electric field applied to a gate insulating layer, and a time period of application of electric field. The intensity of the electric field applied to the gate insulating layer is determined in accordance with a value obtained by dividing a potential difference between the gate electrode layer, and the source electrode layer and the drain electrode layer by the thickness of the gate insulating layer. For example, in the case where the intensity of the electric field applied to the gate insulating layer with a thickness of 100 nm is to be 2 MV/cm, the potential difference may be set to 20 V.

Note that a voltage refers to the difference between potentials of two points, and a potential refers to electrostatic energy (electric potential energy) of a unit charge at a given point in an electrostatic field. Note that in general, a difference between a potential of one point and a reference potential is merely called a potential or a voltage, and a potential and a voltage are used as synonymous words in many cases. Thus, in this specification, a potential may be rephrased as a voltage and a voltage may be rephrased as a potential unless otherwise specified.

Both the +BT test and the −BT test were performed under the following conditions: the substrate temperature was 150° C.; the intensity of an electric field applied to the gate insulating layer was 2 MV/cm; and the time for application was an hour.

First, the +BT test is described. In order to measure initial characteristics of the transistor subjected to the BT test, a change in characteristics of the source-drain current (hereinafter, referred to as the drain current or Id), that is, Vg-Id characteristics were measured under the conditions that the substrate temperature was set to 40° C., the voltage between source and drain electrode layers (hereinafter, the drain voltage or Vd) was set to 10 V, and the voltage between the source electrode layer and the gate electrode layer (hereinafter, the gate voltage or Vg) was changed from −20 V to +20 V. Here, as a countermeasure against moisture absorption onto surfaces of the samples, the substrate temperature was set to 40° C. However, the measurement may be performed at room temperature (25° C.) if there is no particular problem.

Next, the substrate temperature was increased to 150° C., and then, the potential of the source electrode layer and the drain electrode layer of the transistor was set to 0 V. Then, voltage was applied to the gate electrode layer so that the intensity of an electric field applied to the gate insulating layer was 2 MV/cm. Since the thickness of the gate insulating layer in the transistor was 100 nm here, a voltage of +20 V was kept being applied to the gate for an hour. The time of voltage application was an hour here; however, the time may be determined as appropriate in accordance with the purpose.

Next, the substrate temperature was decreased to 40° C. while voltage is applied between the gate electrode layer and the source and drain electrode layers. If application of the voltage is stopped before the substrate temperature was completely decreased to 40° C., the transistor which has been damaged during the BT test is repaired by the influence of residual heat. Thus, the substrate temperature must be decreased while the voltage is being applied. After the substrate temperature was decreased to 40° C., the application of the voltage was stopped. Strictly, the time of decreasing temperature must be added to the time of the voltage application; however, since the temperature was able to be decreased to 40° C. in several minutes actually, this was considered to be an error range and the time of decreasing temperature was not added to the time of application.

Then, Vg-Id characteristics were measured under the same conditions as those of the measurement of the initial characteristics, and Vg-Id characteristics after the +BT test were obtained.

Next, the −BT test is described. The −BT test was performed with the procedure similar to that of the +BT test, but has a different point from the +BT test, in that the voltage applied to the gate electrode layer is set to −20 V after the substrate temperature is increased to 150° C.

In the BT test, it is important to use a transistor which has been never subjected to a BT test. For example, if a −BT test is performed with use of a transistor which has been once subjected to a +BT test, the results of the −BT test cannot be evaluated correctly due to influence of the +BT test which has been performed previously. Further, the same applies to the case where a +BT test is performed on a transistor which has been once subjected to a +BT test. Note that the same does not apply to the case where a BT test is intentionally repeated in consideration of these influences.

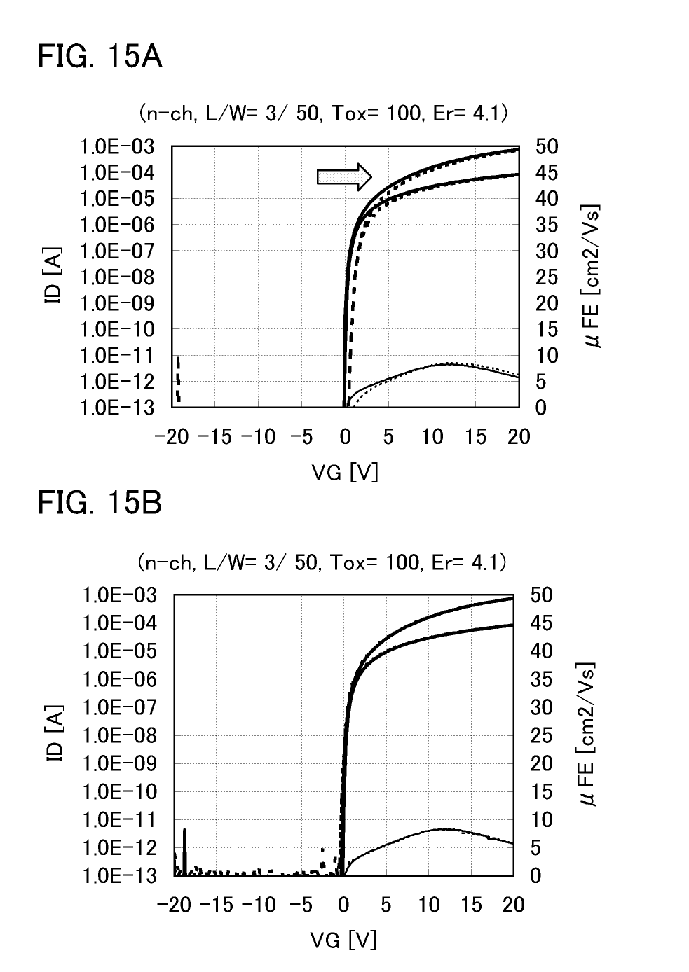

FIG. 15A shows the Vg-Id characteristics of a transistor of Sample 1 before and after performance of the +BT test. In FIG. 15A, the threshold voltage is shifted by 0.93 V in the positive direction as compared with the threshold voltage in the initial characteristics.

FIG. 15B shows the Vg-Id characteristics of a transistor of Sample 1 before and after performance of the −BT test. In FIG. 15B, the threshold voltage is shifted by 0.02 V in the positive direction as compared with the threshold voltage in the initial characteristics.

In both the BT tests, the amount of shift in the threshold voltage of the transistors Sample 1 is less than or equal to 1 V, which confirms that the transistor manufactured in accordance with Embodiment 4 has high reliability. Further, the amount of the shift value (Δshift) of FIG. 15A was 0.858 V, and the amount of the shift value (Δshift) of FIG. 15B was 0.022 V.

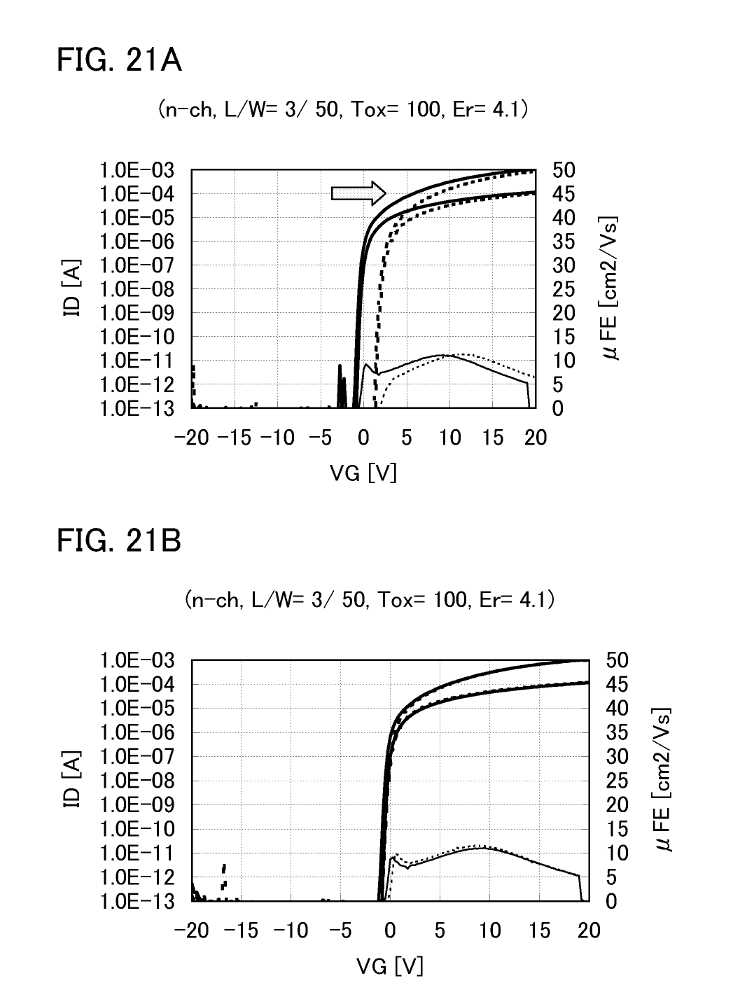

FIG. 21A shows the Vg-Id characteristics of a transistor of Sample A before and after performance of the +BT test. In FIG. 21A, the threshold voltage is shifted by 2.8 V in the positive direction as compared with the threshold voltage in the initial characteristics.

FIG. 21B shows the Vg-Id characteristics of a transistor of Sample A before and after performance of the −BT test. In FIG. 21B, the threshold voltage is shifted by 0.22 V in the positive direction as compared with the threshold voltage in the initial characteristics. Further, the amount of the shift value (Δshift) of FIG. 21A was 2.296 V, and the amount of the shift value (Δshift) of FIG. 21B was 0.247 V.

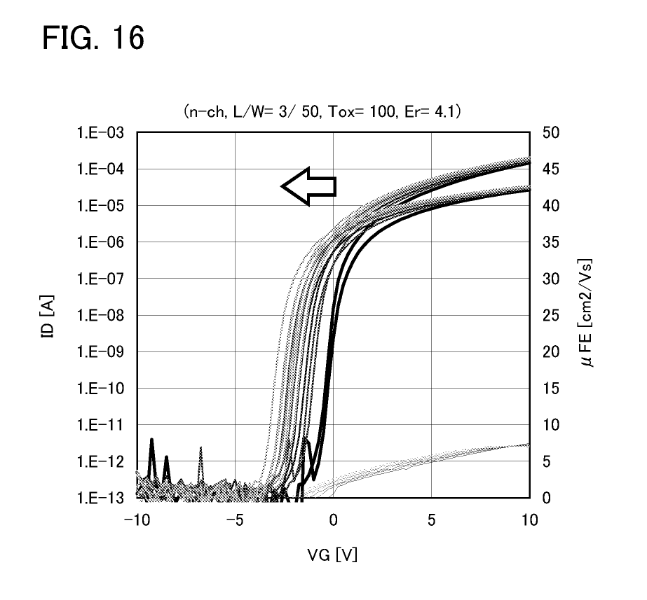

Then, a BT test was performed on the transistors of Sample 1 and Sample A manufactured in this example while the transistors were irradiated with light. Needless to say, Sample used here was different from Sample on which the above BT test was performed. The test method is the same as that of the above BT test, except for points that the transistors were irradiated with light of 36000 lux from a LED light source and the measurement was performed at room temperature (25° C.). Since there was almost no change between before and after performance of +BT test while the transistors were irradiated with light, the description of the results were omitted here. The results of −BT test performed while Sample 1 was irradiated with light are shown in FIG. 16.

FIG. 16 shows the Vg-Id characteristics of the transistor of Sample 1 before and after the −BT test performed while the transistor was irradiated with light. In FIG. 16, the threshold voltage is shifted by 1.88 V in the negative direction as compared with the threshold voltage in the initial characteristics. Further, the amount of the shift value (Δshift) of FIG. 16 was −2.167 V.

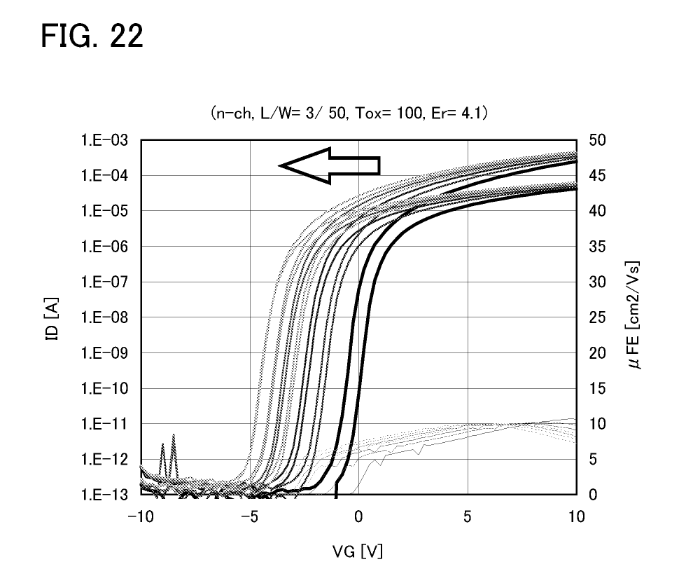

FIG. 22 shows the Vg-Id characteristics of the transistor of Sample A before and after the −BT test performed while the transistor was irradiated with light. In FIG. 22, the threshold voltage is shifted by 4.02 V in the negative direction as compared with the threshold voltage in the initial characteristics. Further, the amount of the shift value (Δshift) of FIG. 22 was −3.986 V.

In the −BT test performed while the transistor was irradiated with light, the amount of shift in the threshold voltage of the transistor of Sample 1 can be equal to or less than half of that of the transistor of Sample A, which confirms that the transistor manufactured in accordance with Embodiment 4 has high reliability.

### Example 2

In this example, the following experiment was conducted in order to examine a crystal state in an oxide semiconductor layer.

A first oxide semiconductor layer with a thickness of 5 nm was formed over a quartz substrate under the same film formation condition as Sample 1 described in Example 1. Then, a first heat treatment was performed at 450° C. in a nitrogen atmosphere for an hour. Next, a second oxide semiconductor layer with a thickness of 25 nm was formed under the same film formation condition as Sample 1. Then, a second heat treatment was performed on the second oxide semiconductor layer at 450° C. in a nitrogen atmosphere for an hour.

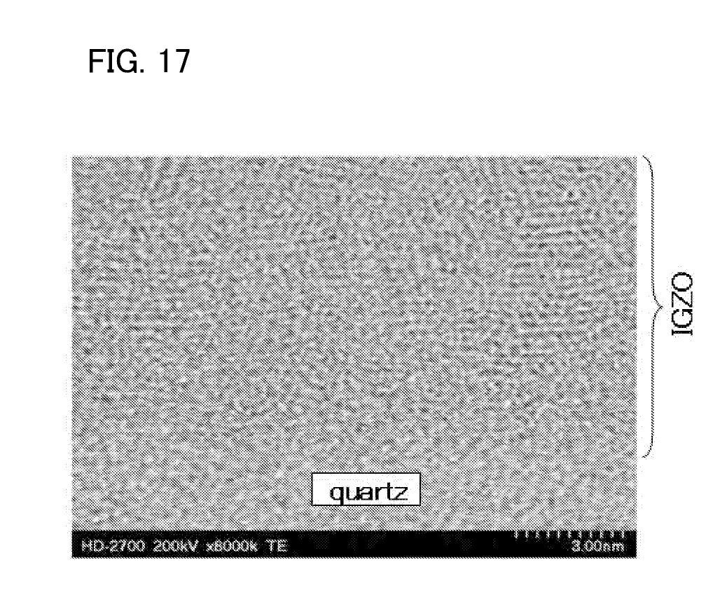

A cross section of the thus obtained sample was observed with a scanning transmission electron microscope (STEM: the Hitachi “HD-2700”) at an acceleration voltage of 200 kV. FIG. 17 shows a high-magnification photograph (eight-million-fold magnification) of the cross section of the sample. From FIG. 17, it can be found that crystal grows in the film thickness direction to form a layered shape. It was difficult to observe a border between the first oxide semiconductor layer and the second oxide semiconductor layer.

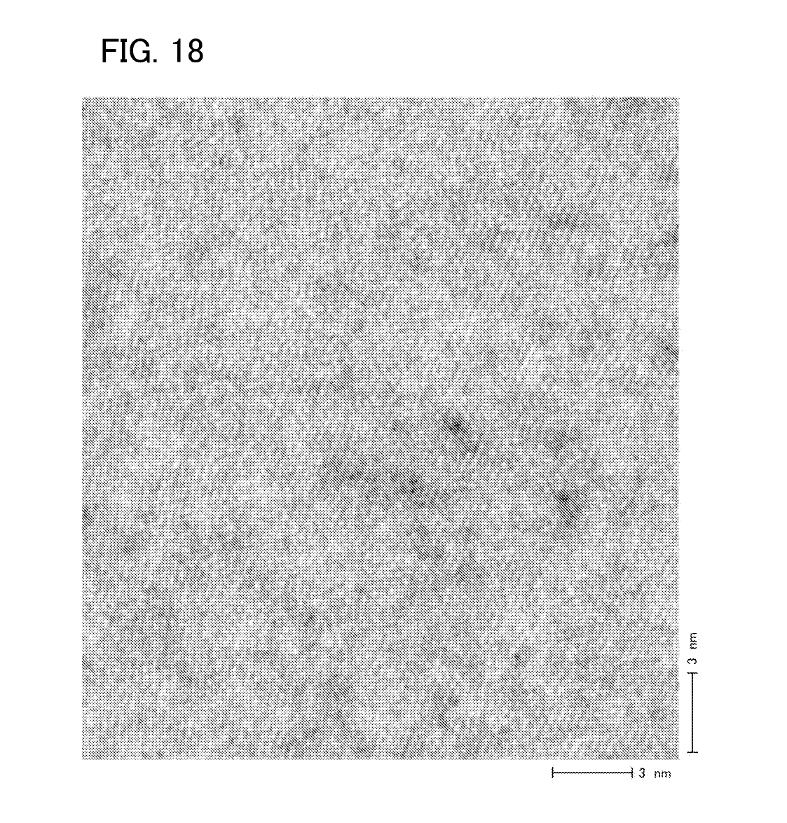

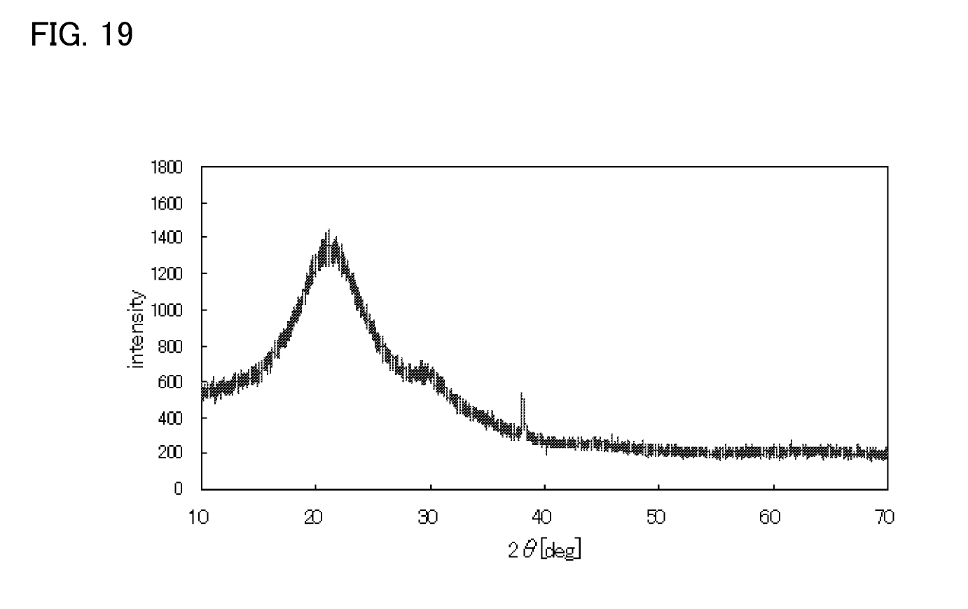

FIG. 18 shows a photograph of a plane surface of the sample which was observed with a transmission electron microscope (TEM). From FIG. 18, a hexagonal lattice image can be observed. FIG. 19 shows a result of analysis of the crystal state by X-ray diffraction (XRD). In the chart, a peak which can be seen within the range of 2θ from 30° to 36° suggests existence of a diffraction peak obtained from a (009) plane which shows the strongest diffraction intensity in the In—Ga—Zn—O-based crystal material. Thus, a crystal region in the sample can be confirmed by X-ray diffraction.

This application is based on Japanese Patent Application serial No. 2010-178174 filed with Japan Patent Office on Aug. 6, 2010, the entire contents of which are hereby incorporated by reference.

What is claimed is:

1. A method for manufacturing a semiconductor device comprising the steps of:
forming a first crystalline oxide semiconductor layer over an oxide insulating layer;
forming a second crystalline oxide semiconductor layer with a greater thickness than the first crystalline oxide semiconductor layer over and in contact with the first crystalline oxide semiconductor layer;
forming source and drain electrodes over the second crystalline oxide semiconductor layer;
forming a gate insulating layer over the source and drain electrodes; and
forming a gate electrode over the gate insulating layer.

2. The method for manufacturing a semiconductor device according to claim 1, wherein the first crystalline oxide semiconductor layer has a thickness greater than or equal to 1 nm and less than or equal to 10 nm.

3. The method for manufacturing a semiconductor device according to claim 1, wherein the first crystalline oxide semiconductor layer contains zinc and has c-axis alignment.

4. The method for manufacturing a semiconductor device according to claim 1, wherein the second crystalline oxide semiconductor layer contains zinc and has c-axis alignment.

5. The method for manufacturing a semiconductor device according to claim 1, further comprising the step of performing a heat treatment at a temperature higher than or equal to 400° C. and lower than or equal to 750° C. after forming the first crystalline oxide semiconductor layer,
wherein the first crystalline oxide semiconductor layer is formed by a sputtering method at a substrate temperature higher than or equal to 200° C. and lower than or equal to 400° C.

6. The method for manufacturing a semiconductor device according to claim 1, further comprising the step of performing a heat treatment at a temperature higher than or equal to 400° C. and lower than or equal to 750° C. after forming the second crystalline oxide semiconductor layer,
wherein the second crystalline oxide semiconductor layer is formed by a sputtering method at a substrate temperature higher than or equal to 200° C. and lower than or equal to 400° C.

7. A method for manufacturing a semiconductor device comprising the steps of:
forming source and drain electrodes over an oxide insulating layer;
forming a first crystalline oxide semiconductor layer over the source and drain electrodes;
forming a second crystalline oxide semiconductor layer with a greater thickness than the first crystalline oxide semiconductor layer over and in contact with the first crystalline oxide semiconductor layer;
forming a gate insulating layer over the second crystalline oxide semiconductor layer; and
forming a gate electrode over the gate insulating layer.

8. The method for manufacturing a semiconductor device according to claim 7, wherein the first crystalline oxide semiconductor layer has a thickness greater than or equal to 1 nm and less than or equal to 10 nm.

9. A method for manufacturing a semiconductor device comprising the steps of:
forming a gate electrode over an oxide insulating layer;
forming a gate insulating layer over the gate electrode;
forming source and drain electrodes over the gate insulating layer;
forming a first crystalline oxide semiconductor layer over the source and drain electrodes; and
forming a second crystalline oxide semiconductor layer with a greater thickness than the first crystalline oxide semiconductor layer over and in contact with the first crystalline oxide semiconductor layer.

10. The method for manufacturing a semiconductor device according to claim 9, wherein the first crystalline oxide semiconductor layer has a thickness greater than or equal to 1 nm and less than or equal to 10 nm.

11. The method for manufacturing a semiconductor device according to claim 9, wherein the first crystalline oxide semiconductor layer contains zinc and has c-axis alignment.

12. The method for manufacturing a semiconductor device according to claim 9, wherein the second crystalline oxide semiconductor layer contains zinc and has c-axis alignment.

13. The method for manufacturing a semiconductor device according to claim 9, further comprising the step of performing a heat treatment at a temperature higher than or equal to 400° C. and lower than or equal to 750° C. after forming the first crystalline oxide semiconductor layer,
wherein the first crystalline oxide semiconductor layer is formed by a sputtering method at a substrate temperature higher than or equal to 200° C. and lower than or equal to 400° C.

14. The method for manufacturing a semiconductor device according to claim 9, further comprising the step of performing a heat treatment at a temperature higher than or equal to 400° C. and lower than or equal to 750° C. after forming the second crystalline oxide semiconductor layer,
wherein the second crystalline oxide semiconductor layer is formed by a sputtering method at a substrate temperature higher than or equal to 200° C. and lower than or equal to 400° C.

15. A method for manufacturing a semiconductor device comprising the steps of:
forming a gate electrode over an oxide insulating layer;
forming a gate insulating layer over the gate electrode;
forming a first crystalline oxide semiconductor layer over the gate insulating layer;
forming a second crystalline oxide semiconductor layer with a greater thickness than the first crystalline oxide semiconductor layer over and in contact with the first crystalline oxide semiconductor layer; and
forming source and drain electrodes over the second crystalline oxide semiconductor layer.

16. The method for manufacturing a semiconductor device according to claim 15, wherein the first crystalline oxide semiconductor layer has a thickness greater than or equal to 1 nm and less than or equal to 10 nm.

17. A semiconductor device comprising:
a first crystalline oxide semiconductor layer over an oxide insulating layer; and
a second crystalline oxide semiconductor layer with a greater thickness than the first crystalline oxide semiconductor layer over and in contact with the first crystalline oxide semiconductor layer,
wherein the first crystalline oxide semiconductor layer has c-axis alignment.

18. The semiconductor device according to claim 17, further comprising:
an n⁺ layer over and in contact with the second crystalline oxide semiconductor layer; and
source and drain electrodes in contact with the n⁺ layer.

19. The semiconductor device according to claim 18, wherein the first crystalline oxide semiconductor layer has a thickness greater than or equal to 1 nm and less than or equal to 10 nm.

20. The semiconductor device according to claim 18, wherein the second crystalline oxide semiconductor layer has c-axis alignment.

21. The semiconductor device according to claim 18, wherein at least one of the first crystalline oxide semiconductor layer and the second crystalline oxide semiconductor layer contains zinc.

22. The semiconductor device according to claim 18, wherein at least one of the first crystalline oxide semiconductor layer and the second crystalline oxide semiconductor layer contains zinc and indium.

23. A semiconductor device comprising:
a first crystalline oxide semiconductor layer over an oxide insulating layer;
a second crystalline oxide semiconductor layer with a greater thickness than the first crystalline oxide semiconductor layer over and in contact with the first crystalline oxide semiconductor layer;
an n⁺ layer over and in contact with the second crystalline oxide semiconductor layer;
source and drain electrodes over and in contact with the n⁺ layer;
a gate insulating layer over the source and drain electrodes, and the second crystalline oxide semiconductor layer; and
a gate electrode over the gate insulating layer to overlap with the first crystalline oxide semiconductor layer and the second crystalline oxide semiconductor layer,
wherein the first crystalline oxide semiconductor layer has c-axis alignment.

24. The semiconductor device according to claim 23, wherein the first crystalline oxide semiconductor layer has a thickness greater than or equal to 1 nm and less than or equal to 10 nm.
